(19) United States
(12) Patent Application Publication
(10) Pub. No.: US 2024/0363695 A1
(43) Pub. Date: Oct. 31, 2024

(54) SEMICONDUCTOR DEVICE

(71) Applicant: Flosfia Inc., Kyoto (JP)

(72) Inventors: Takashi SHINOHE, Kyoto (JP); Mitsuru OKIGAWA, Kyoto (JP); Koji AMAZUTSUMI, Kyoto (JP); Yasushi HIGUCHI, Kyoto (JP); Tokiyoshi MATSUDA, Kyoto (JP)

(21) Appl. No.: 18/771,277

(22) Filed: Jul. 12, 2024

Related U.S. Application Data
(63) Continuation-in-part of application No. PCT/JP2023/000682, filed on Jan. 12, 2023.

(30) Foreign Application Priority Data
Jan. 14, 2022 (JP) 2022-004696

(51) Int. Cl. H01L 29/24; H01L 29/739; H01L 29/778; H01L 29/868; H01L 29/872

(52) U.S. Cl. CPC H01L 29/24; H01L 29/7395; H01L 29/7786; H01L 29/868; H01L 29/872

(57) ABSTRACT

Provided is a semiconductor device including at least: an n type oxide semiconductor layer; a first p type oxide semiconductor layer that forms a main junction with the n type oxide semiconductor layer, and a hole supply layer, wherein the hole supply layer includes a second p type oxide semiconductor layer that is different from the first p type oxide semiconductor layer.

### CROSS REFERENCE TO RELATED APPLICATION

This application is a continuation-in-part application of International Patent Application No. PCT/JP2023/000682 (Filed on Jan. 12, 2023), which claims the benefit of priority from Japanese Patent Application No. 2022-004696 (filed on Jan. 14, 2023).

The entire contents of the above applications, which the present application is based on, are incorporated herein by reference.

### FIELD OF THE INVENTION

The present disclosure relates to a semiconductor device that is useful as a power device or the like.

### DESCRIPTION OF THE RELATED ART

Gallium oxide (Ga₂O₃) is a transparent semiconductor that has a band gap that is as broad as 4.8 eV to 5.3 eV at a room temperature and hardly absorbs visible light and ultraviolet light. Therefore, gallium oxide is a promising material for use in optical/electronic devices and transparent electronics that operate in a deep ultraviolet ray region, in particular, and optical detectors, light emitting diodes (LEDs), and transistors based on gallium oxide (Ga₂O₃) have been developed in recent years. Mixed with indium or aluminum solely or in combination to form a mixed crystal, gallium oxide is controllable in terms of band gaps, constituting a very attractive family of material as InAlGaO-based semiconductors. Here, InAlGaO-based semiconductors indicate In_{X}Al_{Y}Ga_{Z}O₃ (0≤X≤2, 0≤Y≤2, 0≤Z≤2, X+Y+Z=1.5 to 2.5) and may be regarded as a family of materials including gallium oxide.

### SUMMARY OF THE INVENTION

According to an example of the present disclosure, there is provided a semiconductor device including at least: an n type oxide semiconductor layer; a first p type oxide semiconductor layer that forms a main junction with the n type oxide semiconductor layer, and a hole supply layer, wherein the hole supply layer includes a second p type oxide semiconductor layer that is different from the first p type oxide semiconductor layer.

According to an example of the present disclosure, there is provided a semiconductor device including at least: a collector layer; a drift layer; and a well layer, the drift layer including an n type oxide semiconductor layer, the well layer including a first oxide semiconductor layer, the collector layer including a second oxide semiconductor layer that is different from the first oxide semiconductor layer and being an insulated gate bipolar transistor.

According to an example of the present disclosure, there is provided a semiconductor device including at least: an n type oxide semiconductor layer; a Schottky electrode that is provided on the n type oxide semiconductor layer; and a barrier layer that is provided in at least a part between the n type oxide semiconductor layer and the Schottky electrode, the barrier layer including a first oxide semiconductor layer and a second oxide semiconductor layer that is different from the first oxide semiconductor layer and being a junction barrier Schottky diode.

According to an example of the present disclosure, there is provided a semiconductor device including at least: a p type oxide semiconductor layer, an i type oxide semiconductor layer, and an n type oxide semiconductor layer, the p type oxide semiconductor layer including a first oxide semiconductor layer and a second oxide semiconductor layer that is different from the first oxide semiconductor layer and being a PiN diode.

Thus, in a semiconductor device of the present disclosure, it is possible to provide a semiconductor device with excellent semiconductor characteristics.

### BRIEF DESCRIPTION OF THE DRAWINGS

FIG. 1 is a diagram schematically illustrating an insulated gate bipolar transistor (IGBT) according to an embodiment of the present disclosure.

FIG. 2 is a diagram schematically illustrating a PiN diode according to the embodiment of the present disclosure.

FIG. 3 is a diagram schematically illustrating the PiN diode according to the embodiment of the present disclosure.

FIG. 4 is a diagram schematically illustrating a junction barrier Schottky diode (JBS) according to the embodiment of the present disclosure.

FIG. 5 is a diagram schematically illustrating a metal-oxide-semiconductor field-effect transistor (MOSFET) according to the embodiment of the present disclosure.

FIG. 6 is a diagram illustrating results of I-V measurement in an example and a comparative example. The vertical axis represents a current, and the horizontal axis represents a voltage.

FIG. 7 is a configuration diagram of a mist CVD device used in the embodiment of the present disclosure.

FIG. 8 is a block diagram illustrating an example of a control system applying the semiconductor device according to an embodiment of the disclosure.

FIG. 9 is a circuit diagram illustrating an example of the control system applying the semiconductor device according to an embodiment of the disclosure.

FIG. 10 is a block configuration diagram illustrating another example of the control system applying the semiconductor device according to an embodiment of the disclosure.

FIG. 11 is a circuit diagram illustrating another example of the control system applying the semiconductor device according to an embodiment of the disclosure.

FIG. 12 is a diagram schematically illustrating a preferred method of manufacturing the JBS in FIG. 4.

FIG. 13 is a diagram schematically illustrating a preferred method of manufacturing the JBS in FIG. 4.

### DETAILED DESCRIPTION

The present inventors have found that a semiconductor device that includes at least an n type oxide semiconductor layer, a first p type oxide semiconductor layer forming a main junction with the n type oxide semiconductor layer, and a hole supply layer in which the hole supply layer includes a second p type oxide semiconductor layer that is different from the first p type oxide semiconductor layer maintains a voltage withstanding property and has improved semiconductor characteristics such as an ON-state voltage.

Embodiments of the present disclosure will be described below with reference to the accompanying drawings. In the following description, the same parts and components are designated by the same reference numerals. The present embodiment includes, for example, the following disclosures.

### [Structure 1]

A semiconductor device including at least: an n type oxide semiconductor layer; a first p type oxide semiconductor layer that forms a main junction with the n type oxide semiconductor layer, and a hole supply layer, wherein the hole supply layer includes a second p type oxide semiconductor layer that is different from the first p type oxide semiconductor layer.

### [Structure 2]

The semiconductor device according to [Structure 1], wherein the first p type oxide semiconductor layer and the second p type oxide semiconductor layer has a different composition from each other.

### [Structure 3]

The semiconductor device according to [Structure 1] or [Structure 2], wherein a band gap of the first p type oxide semiconductor layer is greater than a band gap of the second p type oxide semiconductor layer.

### [Structure 4]

The semiconductor device according to any one of [Structure 1] to [Structure 3], wherein the first p type oxide semiconductor layer and the second p type oxide semiconductor layer are crystal growth layers.

### [Structure 5]

The semiconductor device according to any one of [Structure 1] to [Structure 4], wherein a bottom surface of the first p type oxide semiconductor layer is located on a side closer to the n type oxide semiconductor layer in a stacking direction of the semiconductor device than a bottom surface of the second p type oxide semiconductor layer.

### [Structure 6]

The semiconductor device according to any one of [Structure 1] to [Structure 5], wherein the n type oxide semiconductor layer contains, as major components, oxides of one or more metals selected from aluminum, gallium, and indium.

### [Structure 7]

The semiconductor device according to any one of [Structure 1] to [Structure 6], wherein the n type oxide semiconductor layer has a corundum structure.

### [Structure 8]

The semiconductor device according to any one of [Structure 1] to [Structure 7], wherein the first p type oxide semiconductor layer contains, as major components, oxides of one or more metals selected from aluminum, gallium, and indium.

### [Structure 9]

The semiconductor device according to any one of [Structure 1] to [Structure 8], wherein the second p type oxide semiconductor layer contains at least oxide of Group 9 metal of the periodic table.

### [Structure 10]

The semiconductor device according to [Structure 9], wherein the Group 9 metal of the periodic table includes iridium.

### [Structure 11]

The semiconductor device according to [Structure 9] or [Structure 10], wherein the second p type oxide semiconductor layer further contains oxides of one or more metals selected from aluminum, gallium, and indium.

### [Structure 12]

The semiconductor device according to any one of [Structure 1] to [Structure 11], wherein the first p type oxide semiconductor layer has a corundum structure.

### [Structure 13]

The semiconductor device according to any one of [Structure 1] to [Structure 12], wherein the second p type oxide semiconductor layer has a corundum structure.

### [Structure 14]

A semiconductor device including at least: a collector layer; a drift layer; and a well layer, the drift layer including an n type oxide semiconductor layer, the well layer including a first oxide semiconductor layer, the collector layer including a second oxide semiconductor layer that is different from the first oxide semiconductor layer and being an insulated gate bipolar transistor.

### [Structure 15]

A semiconductor device including at least: an n type oxide semiconductor layer; a Schottky electrode that is provided on the n type oxide semiconductor layer; and a barrier layer that is provided in at least a part between the n type oxide semiconductor layer and the Schottky electrode, the barrier layer including a first oxide semiconductor layer and a second oxide semiconductor layer that is different from the first oxide semiconductor layer and being a junction barrier Schottky diode.

### [Structure 16]

A semiconductor device including at least: a p type oxide semiconductor layer, an i type oxide semiconductor layer, and an n type oxide semiconductor layer, the p type oxide semiconductor layer including a first oxide semiconductor layer and a second oxide semiconductor layer that is different from the first oxide semiconductor layer and being a PiN diode.

### [Structure 17]

The semiconductor device according to any one of [Structure 14] to [Structure 16], wherein the first oxide semiconductor layer and the second oxide semiconductor layer has a different composition from each other.

### [Structure 18]

The semiconductor device according to any one of [Structure 14] to [Structure 17], wherein a band gap of the first oxide semiconductor layer is greater than a band gap of the second oxide semiconductor layer.

### [Structure 19]

The semiconductor device according to any one of [Structure 14] to [Structure 18], wherein a bottom surface of the first oxide semiconductor layer is located on a side closer to the n type oxide semiconductor layer in a stacking direction of the semiconductor device than a bottom surface of the second oxide semiconductor layer.

### [Structure 20]

The semiconductor device according to any one of [Structure 14] to [Structure 19], wherein hole carrier density of the second oxide semiconductor layer is greater than hole carrier density of the first oxide semiconductor layer.

### [Structure 21]

A power conversion device that uses the semiconductor device according to any one of [Structure 1] to [Structure 20].

### [Structure 22]

A control system that uses the semiconductor device according to any one of [Structure 1] to [Structure 20].

A semiconductor device according to an embodiment of the present disclosure includes at least: an n type oxide semiconductor layer; a first p type oxide semiconductor layer that forms a main junction with the n type oxide semiconductor layer, and a hole supply layer, and is characterized in that the hole supply layer includes a second p type oxide semiconductor layer that is different from the first p type oxide semiconductor layer.

The hole supply layer is not particularly limited as long as hole density is greater than electron density, holes are supplied from the hole supply layer to another layer (such as an n type oxide semiconductor layer) when the semiconductor device is operating (in an ON state), and the hole supply layer does not hinder the present disclosure. In a case where the semiconductor device is an insulated gate bipolar transistor (IGBT), the hole supply layer constitutes a collector layer. Also, in a case where the semiconductor device is a PiN diode, the hole supply layer constitutes at least a part of a p type semiconductor layer. In a case where the semiconductor device is a junction barrier Schottky diode (JBS), the hole supply layer constitutes at least a part of a barrier layer (such as a p type semiconductor layer) in the JBS. Furthermore, in a case where the semiconductor device is a diode-integrated MOSFET, the hole supply layer constitutes at least a part of a p well layer or a p type anode layer in the diode-integrated MOSFET. Also, the expression “different” in the embodiment of the present disclosure includes not only a case where the compositions of the first p type oxide semiconductor layer (first oxide semiconductor layer) and the second p type oxide semiconductor layer (second oxide semiconductor layer) are different but also a case where the compositions are the same while dopants are different. Note that in the embodiment of the present disclosure, the compositions of the first p type oxide semiconductor layer (first oxide semiconductor layer) and the second p type oxide semiconductor layer (second oxide semiconductor layer) is preferably different from each other. Moreover, the expression “main junction” means an interface having a rectification effect in the embodiment of the present disclosure. The main junction is preferably a PN junction in the embodiment of the present disclosure. Furthermore, the “p type” semiconductor layer in the present disclosure means a semiconductor layer in which hole density is greater than electron density and is not limited to a semiconductor layer that is able to be confirmed as being of a “p type” through hall effect measurement. In a case where the p type oxide semiconductor layer is used as a channel layer, for example, the p type oxide semiconductor layer is included in the “p type” as long as the p type oxide semiconductor layer functions as a channel at the time of voltage application.

### (First p Type Oxide Semiconductor Layer/First Oxide Semiconductor Layer)

The first p type oxide semiconductor layer and/or the first oxide semiconductor layer (hereinafter, also simply referred to as a “first p type oxide semiconductor layer”) is not particularly limited as long as the first p type oxide semiconductor layer is different from the second p type oxide semiconductor layer (second oxide semiconductor layer). In the embodiment of the present disclosure, the first p type oxide semiconductor layer preferably contains, as a major component, a first crystalline oxide semiconductor. Examples of the first crystalline oxide semiconductor include metal oxides of one kind or two or more kinds of metal selected from aluminum, gallium, indium, iron, chromium, vanadium, titanium, rhodium, nickel, cobalt, and iridium. In the embodiment of the present disclosure, the first crystalline oxide semiconductor preferably contains at least one kind of metal selected from aluminum, indium, and gallium and more preferably contains at least gallium. In the embodiment of the present disclosure, it is also preferable that the first crystalline oxide semiconductor further contains at least one kind of metal selected from the Groups 6 to 10 of the periodic table. Examples of the Group 6 metal of the periodic table include chromium (Cr), molybdenum (Mo), and tungsten (W). In the embodiment of the present disclosure, the Group 6 metal of the periodic table is preferably chromium (Cr). Examples of the Group 7 metal of the periodic table include one kind or two or more kinds of metal or the like selected from manganese (Mn), technetium (Tc), and rhenium (Re). Examples of the Group 8 metal of the periodic table include one kind or two or more kinds of metal or the like selected from iron (Fe), ruthenium (Ru), and osmium (Os). Examples of the Group 9 metal of the periodic table include one kind or two or more kinds of metal or the like selected from cobalt (Co), rhodium (Rh), and iridium.

In the embodiment of the present disclosure, it is also preferable that the first crystalline oxide semiconductor is a mixed crystal containing at least the Group 9 metal of the periodic table and the Group 13 metal of the periodic table. In this case, the first p type oxide semiconductor layer is preferably a mixed crystal of iridium oxide and gallium oxide (for example, α-(Ir, Ga)₂O₃). Moreover, the first p type oxide semiconductor layer may contain a p type dopant in the embodiment of the present disclosure. Examples of the p type dopant include Mg, H, Li, Na, K, Rb, Cs, Fr, Be, Ca, Sr, Ba, Ra, Mn, Fe, Co, Ni, Pd, Cu, Ag, Au, Zn, Cd, Hg, Ti, Pb, N, and P. A crystal structure of the first p type oxide semiconductor layer is not particularly limited unless it interferes with the present disclosure. Examples of the crystal structure of the first p type oxide semiconductor layer include a corundum structure, a β-gallia structure, a hexagonal crystal structure (such as an ε type structure, for example), an orthorhombic crystal structure (such as a κ type structure, for example), a cubic crystal structure, and a tetragonal crystal structure. In the embodiment of the present disclosure, the first p type oxide semiconductor layer preferably has a corundum structure, a β-gallia structure, or a hexagonal crystal structure (such as an ε type structure, for example) and more preferably has a corundum structure. Also, the first p type oxide semiconductor layer is preferably a crystal growth layer (rather than a semiconductor layer formed by ion implantation) in the embodiment of the present disclosure. Note that the expression “major component” means that the first crystalline oxide semiconductor is contained preferably at an atomic ratio of equal to or greater than 50%, more preferably at an atomic ratio of equal to or greater than 70%, and yet further preferably at an atomic ratio of equal to or greater than 90%, or may be contained at an atomic ratio of 100% with respect to all components of the first p type oxide semiconductor layer. In a case where the first crystalline oxide semiconductor is gallium oxide, for example, it is only necessary for gallium oxide to be contained in the first p type oxide semiconductor layer at a proportion that the atomic ratio of gallium in all metal elements contained in the first p type oxide semiconductor layer is equal to or greater than 0.5. In this case, the atomic ratio of gallium in all the metal elements contained in the first p type oxide semiconductor layer is preferably equal to or greater than 0.7 and is more preferably equal to or greater than 0.9. Also, in a case where the first crystalline oxide semiconductor is a mixed crystal of gallium oxide and iridium oxide (for example, α-(Ir, Ga)₂O₃), for example, it is only necessary for the mixed crystal of gallium oxide and iridium oxide to be contained at a proportion that a total atomic ratio of gallium and iridium in all the metal elements in the first p type oxide semiconductor layer is equal to or greater than 0.5. In this case, the total atomic ratio of gallium and iridium in all the metal elements contained in the first p type oxide semiconductor layer is preferably equal to or greater than 0.7 and is more preferably equal to or greater than 0.9.

### (Second p Type Oxide Semiconductor Layer/Second Oxide Semiconductor Layer)

The hole supply layer is not particularly limited as long as the hole supply layer includes the second p type oxide semiconductor layer (second oxide semiconductor layer) that is different from the first p type oxide semiconductor layer (first oxide semiconductor layer). In the embodiment of the present disclosure, the second p type oxide semiconductor layer and/or the second oxide semiconductor layer (hereinafter, also simply referred to as a “second p type oxide semiconductor layer”) preferably contains a second crystalline oxide semiconductor as a major component. Examples of the second crystalline oxide semiconductor include metal oxides or the like containing one kind or two or more kinds of metal selected from aluminum, gallium, indium, iron, chromium, vanadium, titanium, rhodium, nickel, cobalt, and iridium. In the embodiment of the present disclosure, the second crystalline oxide semiconductor preferably contains at least one kind of metal selected from aluminum, indium, and gallium and more preferably contains at least gallium. Moreover, it is also preferable that the second crystalline oxide semiconductor further contains at least one kind of metal selected from the Groups 6 to 10 of the periodic table in the embodiment of the present disclosure. Examples of the Group 6 metal of the periodic table include one kind or two or more kinds of metal selected from chromium (Cr), molybdenum (Mo), and tungsten (W). In the embodiment, the Group 6 metal of the periodic table is preferably chromium (Cr). Examples of the Group 7 metal of the periodic table include one kind or two or more kinds of metal or the like selected from manganese (Mn), technetium (Tc), and rhenium (Re). Examples of the Group 8 metal of the periodic table include one kind or two or more kinds of metal or the like selected from iron (Fe), ruthenium (Ru), and osmium (Os). Examples of the Group 9 metal of the periodic table include one kind or two or more kinds of metal or the like selected from cobalt (Co), rhodium (Rh), and iridium.

In the embodiment of the present disclosure, it is also preferable that the second crystalline oxide semiconductor is a mixed crystal containing at least the Group 9 metal of the periodic table and the Group 13 metal of the periodic table. In this case, the second p type oxide semiconductor layer is preferably a mixed crystal of iridium oxide and gallium oxide (for example, α-(Ir, Ga)₂O₃). Moreover, the second p type oxide semiconductor layer may contain a p type dopant in the embodiment of the present disclosure. Examples of the p type dopant include Mg, H, Li, Na, K, Rb, Cs, Fr, Be, Ca, Sr, Ba, Ra, Mn, Fe, Co, Ni, Pd, Cu, Ag, Au, Zn, Cd, Hg, Ti, Pb, N, and P. A crystal structure of the second p type oxide semiconductor layer is not particularly limited unless it interferes with the present disclosure. Examples of the crystal structure of the second p type oxide semiconductor layer include a corundum structure, a β-gallia structure, a hexagonal crystal structure (such as an ε type structure, for example), an orthorhombic crystal structure (such as a κ type structure, for example), a cubic crystal structure, and a tetragonal crystal structure. In the embodiment of the present disclosure, the second p type oxide semiconductor layer preferably has a corundum structure, a β-gallia structure, or a hexagonal crystal structure (such as an ε type structure, for example) and more preferably has a corundum structure. Also, the second p type oxide semiconductor layer is preferably a crystal growth layer (rather than a semiconductor layer formed by ion implantation) in the embodiment of the present disclosure.

Note that the expression “major component” means that the second crystalline oxide semiconductor is contained preferably at an atomic ratio of equal to or greater than 50%, more preferably at an atomic ratio of equal to or greater than 70%, and yet further preferably at an atomic ratio of equal to or greater than 90%, or may be contained at an atomic ratio of 100% with respect to all components of the second p type oxide semiconductor layer. In a case where the second crystalline oxide semiconductor is gallium oxide, for example, it is only necessary for gallium oxide as the second crystalline oxide semiconductor to be contained in the second p type oxide semiconductor layer at a proportion that the atomic ratio of gallium in all metal elements contained in the second p type oxide semiconductor layer is equal to or greater than 0.5. In this case, the atomic ratio of gallium in all the metal elements contained in the second p type oxide semiconductor layer is preferably equal to or greater than 0.7 and is more preferably equal to or greater than 0.9. Also, in a case where the second crystalline oxide semiconductor is a mixed crystal of gallium oxide and iridium oxide (for example, α-(Ir, Ga)₂O₃), for example, it is only necessary for the mixed crystal of gallium oxide and iridium oxide to be contained at a proportion that a total atomic ratio of gallium and iridium in all the metal elements in the second p type oxide semiconductor layer is equal to or greater than 0.5. In this case, the total atomic ratio of gallium and iridium in all the metal elements contained in the second p type oxide semiconductor layer is preferably equal to or greater than 0.7 and is more preferably equal to or greater than 0.9. Also, in a case where the second crystalline oxide semiconductor is a mixed crystal of gallium oxide and chromium oxide (for example, α-(Cr, Ga)₂O₃), for example, it is only necessary for the mixed crystal of gallium oxide and chromium oxide to be contained at a proportion that a total atomic ratio of gallium and chromium in all the metal elements in the second p type oxide semiconductor layer is equal to or greater than 0.5. In this case, the total atomic ratio of gallium and chromium in all the metal elements contained in the second p type oxide semiconductor layer is preferably equal to or greater than 0.7 and is more preferably equal to or greater than 0.9.

In the embodiment of the present disclosure, a band gap of the first p type oxide semiconductor layer is preferably greater than a band gap of the second p type oxide semiconductor layer. The first p type oxide semiconductor has a band gap of equal to or greater than 3.5 eV and preferably a band gap of equal to or greater than 4.0 eV, for example. Also, the band gap of the second p type oxide semiconductor layer is equal to or greater than 2.5 eV and is preferably equal to or greater than 3.0 eV, for example. Moreover, the first p type oxide semiconductor layer and the second p type oxide semiconductor layer have different compositions in the embodiment of the present disclosure. More specifically, in a case where both the first p type oxide semiconductor layer and the second p type oxide semiconductor layer are mixed crystals of gallium oxide and iridium oxide, for example, the atomic ratio of gallium and iridium in the first p type oxide semiconductor layer and the atomic ratio of gallium and iridium in the second p type oxide semiconductor layer are preferably different from each other. Also, hole carrier density of the second p type oxide semiconductor layer is preferably greater than hole carrier density of the first p type oxide semiconductor layer in the embodiment of the present disclosure. The hole carrier density of the first p type oxide semiconductor layer is within a range of 1.0×10¹⁶/cm³ to 1.0×10¹⁸/cm³, for example. Also, the hole carrier density of the second p type oxide semiconductor layer is within a range of 5.0×10¹⁷/cm³ to 1.0 to 10²⁰/cm³, for example. It is possible to further reduce an ON-state voltage of the semiconductor device and to further improve a voltage withstanding property by using different p type oxide semiconductor layers as described above. In the embodiment of the present disclosure, a bottom surface of the first p type oxide semiconductor layer is preferably located on the side closer to the n type oxide semiconductor layer in a stacking direction of the semiconductor device than a bottom surface of the second p type oxide semiconductor layer. With such a preferable structure, it is possible to achieve an effect of improving electrical characteristics such as an ON-state voltage without degrading a voltage withstanding property of the semiconductor device even in a case where a material with a band gap that is smaller than the band gap of the first p type oxide semiconductor layer is used as the second p type oxide semiconductor layer, for example. The thicknesses of the first p type oxide semiconductor layer and the second p type oxide semiconductor layer are not particularly limited unless they interfere with the present disclosure. The thickness of the first p type oxide semiconductor layer is preferably greater than the thickness of the second p type oxide semiconductor layer. The thickness of the first p type oxide semiconductor layer is within a range of 0.1 μm to 5.0 μm, for example. The thickness of the second p type oxide semiconductor layer is within a range of 0.01 μm to 3.0 μm, for example. Also, the first p type oxide semiconductor layer and the second p type oxide semiconductor layer are preferably crystal growth layers in the embodiment of the present disclosure. With such a preferable configuration, it is possible to more satisfactorily express functions of the first p type oxide semiconductor layer and the second p type oxide semiconductor layer in the combination with the n type oxide semiconductor layer.

### (n Type Oxide Semiconductor Layer)

The n type oxide semiconductor layer is not particularly limited as long as the n type oxide semiconductor layer is an oxide semiconductor layer with n type electrical conductivity and unless it interferes with the present disclosure. In the embodiment of the present disclosure, the n type oxide semiconductor layer preferably contains a crystalline oxide semiconductor as a major component. Examples of the crystalline oxide semiconductor include metal oxides or the like containing one kind or two or more kinds of metal selected from aluminum, gallium, indium, iron, chromium, vanadium, titanium, rhodium, nickel, cobalt, and iridium. In the embodiment of the present disclosure, the crystalline oxide semiconductor preferably contains at least one kind of metal selected from aluminum, indium, and gallium, more preferably contains at least gallium, and is most preferably α-Ga₂O₃ or a mixed crystal thereof. The crystal structure of the n type oxide semiconductor layer is also not particularly limited unless it interferes with the present disclosure. Examples of the crystal structure of the n type oxide semiconductor layer include a corundum structure, a β-gallia structure, a hexagonal crystal structure (such as an ε type structure, for example), an orthorhombic crystal structure (such as a κ type structure, for example), a cubic crystal structure, and a tetragonal crystal structure. In the embodiment of the present disclosure, the n type oxide semiconductor layer preferably has a corundum structure, a β-gallia structure, or a hexagonal crystal structure (such as an ε type structure, for example) and more preferably has a corundum structure. Note that the expression “major component” means that the crystalline oxide semiconductor is contained preferably at an atomic ratio of equal to or greater than 50%, more preferably at an atomic ratio of equal to or greater than 70%, and yet further preferably at an atomic ratio of equal to or greater than 90%, or may be contained at an atomic ratio of 100% with respect to all components of the n type oxide semiconductor layer. In a case where the crystalline oxide semiconductor is gallium oxide, for example, it is only necessary for gallium oxide as the crystalline oxide semiconductor to be contained in the n type oxide semiconductor layer at a proportion that the atomic ratio of gallium in all metal elements contained in the n type oxide semiconductor layer is equal to or greater than 0.5. The atomic ratio of gallium in all the metal elements contained in the n type oxide semiconductor layer is preferably equal to or greater than 0.7 and is more preferably equal to or greater than 0.9. Also, although the thickness of the n type oxide semiconductor layer is not particularly limited and may be equal to or less than 1 μm or may be equal to or greater than 1 μm, the thickness of the n type oxide semiconductor layer is preferably equal to or greater than 5 μm and is more preferably equal to or greater than 10 μm in the embodiment of the present disclosure. Although a surface area (in a plan view) of the semiconductor film is not particularly limited and may be equal to or greater than 1 mm² or may be equal to or less than 1 mm², the surface area of the semiconductor film is preferably 10 mm² to 300 mm² and is more preferably 10 mm² to 100 mm². Also, although the n type oxide semiconductor layer is typically monocrystalline, the n type oxide semiconductor layer may be polycrystalline. Also, the n type oxide semiconductor layer typically includes two or more semiconductor layers. The n type oxide semiconductor layer includes at least an n+ type semiconductor layer, a drift layer (n− type semiconductor layer), a channel layer, and a source region (n+ type semiconductor layer), for example. Specific functions of the n type semiconductor layer in the semiconductor device will be described later along with explanation of drawings. Also, it is possible to appropriately set carrier density of the n type oxide semiconductor layer by adjusting the amount of doping.

The n type oxide semiconductor layer preferably contains an n type dopant. The n type dopant is not particularly limited and may be a known dopant. In the embodiment of the present disclosure, preferred examples of the n type dopant include n type dopants or the like such as tin, germanium, silicon, titanium, zirconium, vanadium, and niobium, for example, particularly in a case where the n type oxide semiconductor contains, as a major component, a crystalline oxide semiconductor containing gallium. In the embodiment of the present disclosure, the n type dopant is preferably at least one kind selected from Sn, Ge, and Si. The content of the n type dopant is preferably equal to or greater than 0.00001 at %, is more preferably 0.00001 at % to 20 at %, and is most preferably 0.00001 at % to 10 at % in the composition of the semiconductor layer. More specifically, the concentration of the n type dopant may be typically about 1×10¹⁶/cm³ to 1×10²²/cm³, or the concentration of the n type dopant may be as low as about 1×10¹⁷/cm³ or less. Furthermore, according to the present disclosure, the dopant may be contained at a concentration that is as high as about 1×10²⁰/cm³ or more.

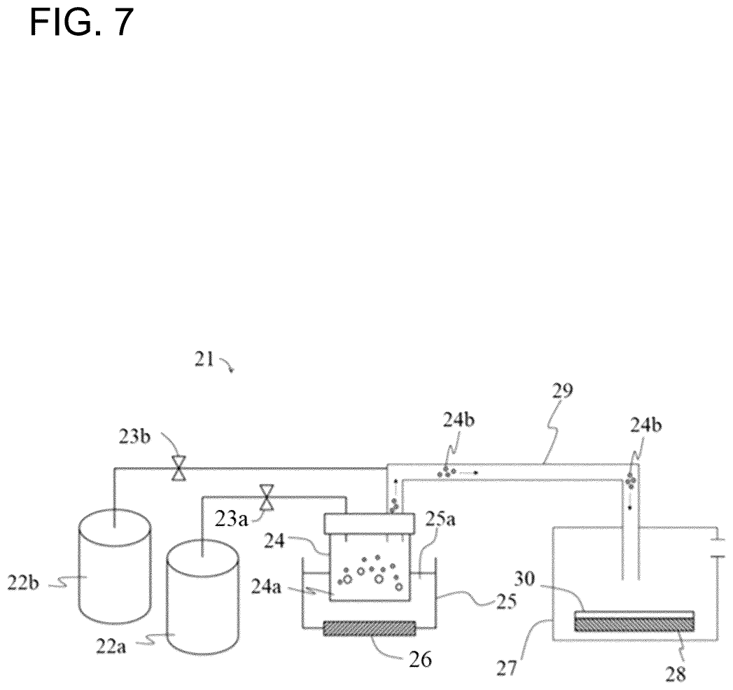

The n type oxide semiconductor layer or the p type oxide semiconductor layer (hereinafter, also simply referred to as an “oxide semiconductor layer”, “semiconductor film”, or a “semiconductor layer”) may be formed using known means. Examples of the means for forming the semiconductor layer include a CVD method, an MOCVD method, an MOVPE method, a mist CVD method, a mist epitaxy method, an MBE method, an HVPE method, a pulse growth method, and an ALD method. In the embodiment of the present disclosure, the means for forming the semiconductor layer is preferably an MOCVD method, a mist CVD method, a mist epitaxy method, or an HVPE method and is preferably a mist CVD method or a mist epitaxy method. In the mist CVD method or the mist epitaxy method, a raw material solution is atomized (atomization process) using a mist CVD device illustrated in FIG. 7, for example, liquid droplets are caused to float, the thus obtained atomized liquid droplets are transported to a base with carrier gas (transport process), the atomized liquid droplets are then caused to thermally react in the vicinity of the base, a semiconductor film is thereby stacked on the base (film formation process), and the semiconductor layer is thereby formed.

### (Atomization Process)

In the atomization process, the raw material solution is atomized. Means for atomizing the raw material solution is not particularly limited as long as the means is able to atomize the raw material solution and may be known means, and atomization means using ultrasonic waves is preferable in the embodiment of the present disclosure. An initial speed of the atomized liquid droplets obtained using ultrasonic waves is zero, the atomized liquid droplets are preferable since they float in the air, and the atomized liquid droplets are very preferable since they are mist that is able to float in the air and is able to be transported as gas rather than being sprayed, for example, and no damage occurs due to collision energy. The liquid droplet size is not particularly limited, the liquid droplets may have a size of about several mm, and the size is preferably equal to or less than 50 μm and is more preferably 100 nm to 10 μm.

### (Raw Material Solution)

The raw material solution is able to be atomized or transformed into liquid droplets, is not particularly limited as long as the raw material solution contains a raw material capable of forming the semiconductor film, and may be an inorganic material or an organic material. In the embodiment of the present disclosure, the raw material is preferably metal or a metal compound and more preferably includes one kind or two or more kinds of metal selected from aluminum, gallium, indium, iron, chromium, vanadium, titanium, rhodium, nickel, cobalt, and iridium.

In the embodiment of the present disclosure, it is possible to preferably use, as the raw material solution, a solution obtained by dissolving or dispersing the metal in the form of a complex or a salt in an organic solvent or water. Examples of the form of the complex include an acetylacetonato complex, a carbonyl complex, an ammine complex, and a hydride complex. Examples of the form of the salt include an organic metal salt (such as metal acetate, metal oxalate, and metal citrate, for example), a sulfurized metal salt, a nitrified metal salt, a phosphorylated metal salt, and a halogenated salt (such as a chlorinated metal salt, a brominated metal salt, and an iodized metal salt, for example).

Also, it is preferable to mix an additive such as a hydrohalic acid or an oxidant into the raw material solution. Examples of the hydrohalic acid include a hydrobromic acid, a hydrochloric acid, and hydriodic acid, and particularly, a hydrobromic acid or a hydriodic acid is preferable for a reason that it is possible to more efficiently reduce occurrence of abnormal particles. Examples of the oxidant include peroxides such as hydrogen peroxide (H₂O₂), sodium peroxide (Na₂O₂), barium peroxide (BaO₂), and benzoyl peroxide (C₆H₅CO)₂O₂, and organic peroxides such as a hydrochlorous acid (HClO), a perchloric acid, a nitric acid, ozone water, a peracetic acid, and nitrobenzene.

The raw material solution may contain a dopant. It is possible to satisfactorily perform doping by causing the dopant to be contained in the raw material solution. The dopant is not particularly limited unless it interferes with the present disclosure. Examples of the dopant include n type dopants such as tin, germanium, silicon, titanium, zirconium, vanadium, and niobium and p type dopants such as Mg, H, Li, Na, K, Rb, Cs, Fr, Be, Ca, Sr, Ba, Ra, Mn, Fe, Co, Ni, Pd, Cu, Ag, Au, Zn, Cd, Hg, Ti, Pb, N, and P. The content of the dopant is appropriately set by using a calibration curve indicating a relationship of concentration of the dopant in the raw materials with respect to desired carrier density.

A solvent of the raw material solution is not particularly limited, may be an inorganic solvent such as water, may be an organic solvent such as alcohol, or may be a mixed solvent of an inorganic solvent and an organic solvent. In the embodiment of the present disclosure, the solvent preferably includes water.

### (Transport Process)

In the transport process, the atomized liquid droplets are transported into a film formation chamber with carrier gas. The carrier gas is not particularly limited unless it interferes with the present disclosure, and preferred examples include inert gas such as oxygen, ozone, nitrogen, and argon and reducing gas such as hydrogen gas and forming gas. Although the number of kinds of the carrier gas may be one, the number of kinds of the carrier gas may be two or more, and diluted gas (such as 10-time diluted gas, for example) with a reduced flow rate may be further used as second carrier gas. In addition, the number of carrier gas supply location may not be only one and may be two or more. The flow rate of the carrier gas is not particularly limited, is preferably 0.01 L/minute to 20 L/minute and is more preferably 1 L/minute to 10 L/minute. In the case of diluted gas, the flow rate of the diluted gas is preferably 0.001 L/minute to 5 L/minute and is more preferably 0.1 L/minute to 3 L/minute.

### (Film Formation Process)

In the film formation process, the semiconductor film is formed on the base by causing the atomized liquid droplets to thermally react in the vicinity of the base. The thermal reaction may be performed in any manner as long at the atomized liquid droplets cause a reaction with heat, and reaction conditions and the like are also not particularly limited unless it interferes with the present disclosure. In the process, the thermal reaction is typically performed at a temperature that is equal to or greater than an evaporation temperature of the solvent, is preferably equal to or less than a temperature that is not excessively high (1000° C., for example), is more preferably equal to or less than 650° C., and is most preferably 300° C. to 650° C. Moreover, although the thermal reaction may be performed in any atmosphere out of in vacuum, in a non-oxygen atmosphere (such as an inert gas atmosphere, for example), in a reducing gas atmosphere, and in an oxygen atmosphere, the thermal reaction is preferably performed in an inert gas atmosphere or in an oxygen atmosphere. Also, although the thermal reaction may be performed under any condition out of under an atmospheric pressure, under an increased pressure, and under a reduced pressure, the thermal reaction is preferably performed under an atmospheric pressure in the embodiment of the present disclosure. Note that the film thickness is able to be set by adjusting a film formation time.

### (Base)

The base is not particularly limited as long as the base is able to support the semiconductor film. A material of the base is not particularly limited unless it interferes with the present disclosure, the base may be a known base, and the material may be an organic compound or may be an inorganic compound. The shape of the base may be any shape, the base is effective for any shape, examples of the shape include a plate shape such as a flat plate or a disc, a fiber shape, a rod shape, a columnar shape, a prismatic shape, a tubular shape, a spiral shape, a spherical shape, and a ring shape, and the base is preferably a substrate in the embodiment of the present disclosure. The thickness of the substrate is not particularly limited in the embodiment of the present disclosure.

The substrate is not particularly limited as long as the substrate has a plate shape and serves as a support body of the semiconductor film. Although the substrate may be an insulating substrate, may be a semiconductor substrate, or may be a metal substrate or a conductive substrate, the substrate is preferably an insulating substrate or is also preferably a substrate including a metal film on the surface thereof. Examples of the substrate include an underlayer substrate containing, as a major component, a substrate material having a corundum structure, an underlayer substrate containing, as a major component, a substrate material having a β-gallia structure, and an underlayer substrate containing, as a major component, a substrate material having a hexagonal crystal structure. Here, the “major component” means that the substrate material having the specific crystal structure is contained preferably at an atomic ratio of equal to or greater than 50%, more preferably at an atomic ratio of equal to or greater than 70%, and is further preferably at an atomic ratio of equal to or greater than 90%, and may be contained at 100% with respect to all components of the substrate material.

The substrate material is not particularly limited unless it interferes with the present disclosure unless it interferes with the present disclosure and may be a known substrate material. Preferable examples of the substrate material having the corundum structure described above include α-Al₂O₃ (sapphire substrate) or α-Ga₂O₃, and more preferable examples include an a-plane sapphire substrate, an m-plane sapphire substrate, an r-plane sapphire substrate, a c-plane sapphire substrate, and an α type gallium oxide substrate (an a plane, an m plane, or an r plane). Examples of the underlayer substrate containing, as a major component, a substrate material having a β-gallia structure include a f-Ga₂O₃ substrate and a mixed crystal substrate containing Ga₂O₃ and Al₂O₃ in which Al₂O₃ is greater than 0 wt % and is equal to or less than 60 wt %. Also, examples of the underlayer substrate containing, as a major component, a substrate material having a hexagonal crystal structure include an SiC substrate, a ZnO substrate, and a GaN substrate.

In the embodiment of the present disclosure, annealing processing may be performed after the film formation process. The annealing processing temperature is not particularly limited unless it interferes with the present disclosure, is typically 300° C. to 650° C., and is preferably 350° C. to 550° C. Also, the annealing processing time is typically 1 minute to 48 hours, is preferably 10 minutes to 24 hours, and is more preferably 30 minutes to 12 hours. Note that the annealing processing may be performed in any atmosphere unless it interferes with the present disclosure. The annealing processing may be performed in a non-oxygen atmosphere or may be performed in an oxygen atmosphere. Examples of the non-oxygen atmosphere include an inert gas atmosphere (such as a nitrogen atmosphere, for example) and a reducing gas atmosphere, and the annealing processing is preferably performed in an inert gas atmosphere and is more preferably performed in a nitrogen atmosphere in the embodiment of the present disclosure.

Moreover, the semiconductor film may be provided directly on the substrate, or the semiconductor film may be provided via another layer such as a stress relief layer (such as a buffer layer or an ELO layer, for example) or a removable sacrificial layer in the embodiment of the present disclosure. Means for forming each layer is not particularly limited, may be known means, and is preferably a mist CVD method in the embodiment of the present disclosure.

In the embodiment of the present disclosure, the semiconductor film may be used as the semiconductor layer for a semiconductor device after using known means such as removing from the base or the like or may be directly used as the semiconductor layer for a semiconductor device.

The semiconductor device according to the present disclosure is effective for a variety of semiconductor elements and is effective for a power device, in particular. Also, the semiconductor elements are categorized into a lateral element (lateral device) in which an electrode is formed on a side of one surface of a semiconductor layer and a current flows in a direction perpendicular to a film thickness direction of the semiconductor layer and a vertical element (vertical device) in which electrodes are included on both front and rear surfaces of a semiconductor layer and a current flows in a film thickness direction of the semiconductor layer, the semiconductor element is able to be suitably used both for a lateral device and for a vertical device in the embodiment of the present disclosure, and the semiconductor element is preferably used for a vertical device, in particular. Examples of the semiconductor element include a junction barrier Schottky diode (JBS), a metal semiconductor field effect transistor (MESFET), a metal-oxide-semiconductor field-effect transistor (MOSFET), a static induction transistor (SIT), a junction field effect transistor (JFET), an insulated gate bipolar transistor (IGBT), and a PiN diode (PND). In the embodiment of the present disclosure, the semiconductor device is preferably a JBS, a PND, a MOSFET, an SIT, a JFET, or an IGBT and is more preferably a JBS, a MOSFET, a PND, or an IGBT.

Although preferred examples of the semiconductor device will be described below by using the drawings, the present disclosure is not limited to these embodiments. Note that a semiconductor device illustrated below as an example may further include other layers (such as an insulating layer, a semi-insulating layer, a conductive layer, a semiconductor layer, a relief layer, and another intermediate layer, for example) unless they interfere with the present disclosure, and the relief layer (buffer layer) and the like may be appropriately omitted. Note that in the following description, a case where a first oxide semiconductor layer is a first p type oxide semiconductor layer while a second oxide semiconductor layer is a second p type oxide semiconductor is also included in the embodiments of the present disclosure.

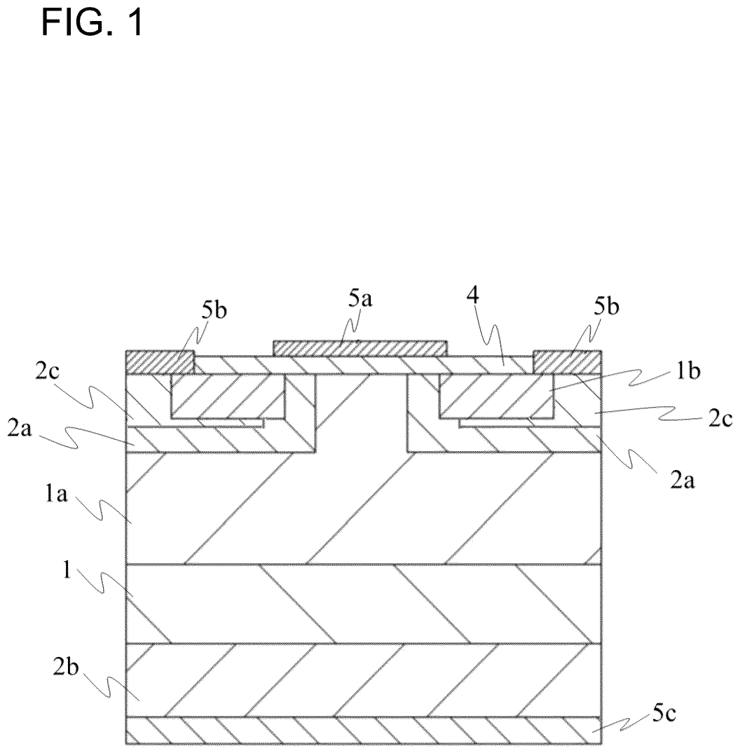

FIG. 1 is a diagram schematically illustrating major parts of an insulated gate bipolar transistor (IGBT) which is one of preferred embodiments of the present disclosure. The IGBT in FIG. 1 includes a collector electrode 5c, a second oxide semiconductor layer (collector layer) 2b as a hole supply layer, an n type oxide semiconductor layer (buffer layer) 1, an n− type oxide semiconductor layer (drift layer) 1a, a first oxide semiconductor layer (well layer) 2a, a third p type oxide semiconductor layer (p contact layer) 2c, an n+ type semiconductor layer (emitter layer) 1b, a gate insulating film 4, an emitter electrode 5b, and a gate electrode 5a. In the IGBT in FIG. 1, the second oxide semiconductor layer (collector layer) 2b, the n type oxide semiconductor layer (buffer layer) 1, and the n− type oxide semiconductor layer 1a are stacked in this order on the collector electrode 5c. Also, the IGBT in FIG. 1 further includes the first oxide semiconductor layer (well layer) 2a disposed on the n− type semiconductor layer 1a on the side of the gate electrode 5a, and the n+ type oxide semiconductor layer (emitter layer) 1b and the third p type oxide semiconductor layer (p contact layer) 2c are included inside the first oxide semiconductor layer 2a. Moreover, the gate electrode 5a is disposed above the first oxide semiconductor layer 2a via a gate insulating film 4. Note that the emitter electrode 5b is disposed to be in Contact with the n+ type oxide semiconductor layer 1b and the third p type oxide semiconductor layer 2c. Note that in the semiconductor device in FIG. 1, the first oxide semiconductor layer (well layer) 2a and the n− type oxide semiconductor layer 1a form a main junction. In the semiconductor device in FIG. 1, a positive voltage is applied between the emitter electrode 5b and the collector electrode 5c in an ON state of the IGBT in FIG. 1, and once a voltage which is positive with respect to the emitter electrode 5b is applied to the gate electrode 5a, a channel is formed in the first oxide semiconductor layer 2a within a range in contact with the gate electrode 5a via the gate insulating film 4. At this time, electrons are supplied from the n+ type oxide semiconductor layer 1b to the n− type oxide semiconductor layer 1a, and holes are supplied from the second oxide semiconductor layer 2b to the n− type oxide semiconductor layer 1a. In this manner, a current flows from the collector electrode 5c to the emitter electrode 5b. Once a potential of the gate electrode 5a is lowered to below a threshold value, the channel disappears, and the IGBT is turned off.

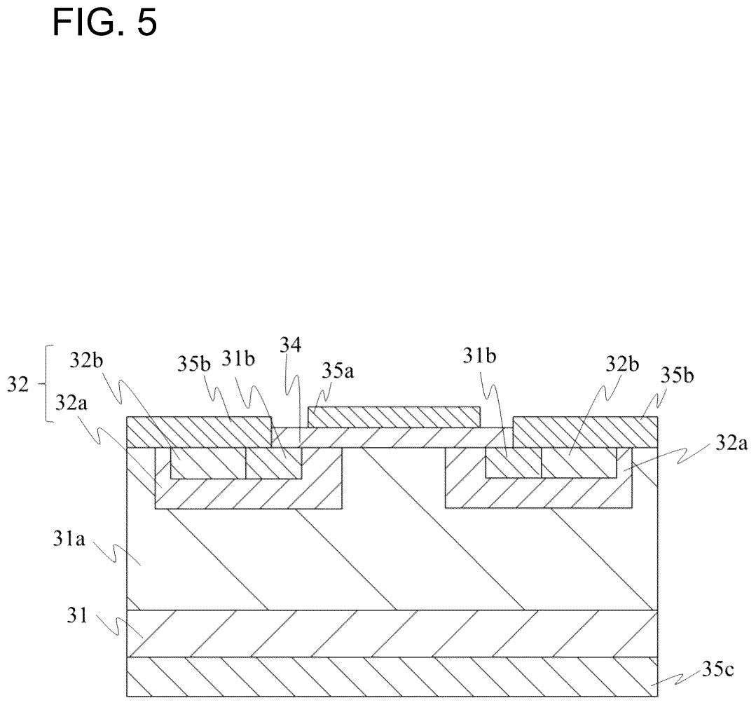

In the IGBT in FIG. 1, the first oxide semiconductor layer 2a has a different composition from a composition of the second oxide semiconductor layer 2b. In the embodiment of the present disclosure, the first oxide semiconductor layer 2a is an α-(Ir, Ga)₂O₃ layer, and the second oxide semiconductor layer 2b is an α-(Ir, Ga)₂O₃ layer that has a different Ir composition and/or Ga composition from an Ir composition and/or Ga composition of the first oxide semiconductor layer. In the embodiment of the present disclosure, a band gap of the first oxide semiconductor layer 2a is preferably greater than a band gap of the second oxide semiconductor layer. With such a preferable configuration, it is possible to more satisfactorily cause conductivity modulation while maintaining a voltage withstanding property of the IGBT and to more satisfactorily supply holes from the collector layer (second oxide semiconductor layer) 2b to the n− type oxide semiconductor layer (drift layer) 1a in the ON state. Also, it is possible to cause maintaining of voltage withstanding achieved by the first oxide semiconductor layer 2a to more satisfactorily function in the OFF state. In the embodiment of the present disclosure, hole carrier density of the second oxide semiconductor layer is preferably greater than hole carrier density of the first oxide semiconductor layer. It is possible to cause hole injection from the second oxide semiconductor layer 2b in a forward direction to more satisfactorily function by setting the hole carrier density within such a preferable range. Also, the third p type oxide semiconductor layer 2c is preferably formed of a material having higher hole carrier density than the first oxide semiconductor layer 2a similarly to the second oxide semiconductor layer 2b. It is thus possible to reduce ohmic contact resistance with the emitter electrode 5b and to prevent breakage of the element by causing an avalanche current to escape to the outside of the element when the IGBT is turned off. Also, it is possible to prevent a latch-up operation of a parasitic thyristor structure including the second oxide semiconductor layer 2b, the n type oxide semiconductor layer (buffer layer) 1, the n− type oxide semiconductor layer (drift layer) 1a, the first oxide semiconductor layer (well layer) 2a, and the n+ type oxide semiconductor layer (emitter layer) 1b. Moreover, it is also possible to use, as a reverse conducting diode, a parasitic PND including the third p type oxide semiconductor layer 2c, the first oxide semiconductor layer 2a, the n− type oxide semiconductor layer (drift layer) 1a, and the n type oxide semiconductor layer (buffer layer) 1 by removing the second oxide semiconductor layer 2b immediately below the emitter electrode 5b. Furthermore, if a Schottky diode is included as in a reverse conducting diode incorporated MOSFET in FIG. 5 as will be described later, it is possible to use the Schottky diode as a reverse conducting diode rising from a low voltage. Note that although a case where the IGBT in FIG. 1 is of a planar gate type has been described as an example, the IGBT may be of a trench gate type in the embodiment of the present disclosure.

A constituent material of the gate insulating film (interlayer insulating film) is not particularly limited and may be a known material. Examples of the material of the gate insulating film include an SiO₂ film, an SiON film, an AlON film, an AlN film, an Al₂O₃ film, an HfO₂ film, a phosphorus-added SiO₂ film (PSG film), a boron-added SiO₂ film (BSG film), and a phosphorus-boron-added SiO₂ film (BPSG film). The material is not limited to these and may be any material that is used for a MOSFET gate insulating film. Also, the gate insulating film may be any of amorphous, polycrystalline, and monocrystalline gate insulating films, or may be a multilayer film. Examples of a method of forming the gate insulating film include a CVD method, an atmospheric pressure CVD method, a plasma CVD method, and a mist CVD method. In the embodiment of the present disclosure, the method of forming the gate insulating film is preferably a mist CVD method or an atmospheric pressure CVD method.

The collector electrode 5c, the emitter electrode 5b, and the gate electrode 5a are not particularly limited as long as the collector electrode 5c, the emitter electrode 5b, and the gate electrode 5a have electrical conductivity and unless they interfere with the present disclosure. A constituent material of the collector electrode 5c, the emitter electrode 5b, and the gate electrode 5a (hereinafter, collectively simply referred to as “electrodes”) may be a conductive inorganic material or may be a conductive organic material. In the embodiment of the present disclosure, the material of the electrode is preferably metal. Preferred examples of the metal include at least one kind of metal selected from the Groups 4 to 10 of the periodic table. Examples of the Group 4 metal of the periodic table include titanium (Ti), zirconium (Zr), and hafnium (Hf). Examples of the Group 5 metal of the periodic table include vanadium (V), niobium (Nb), and tantalum (Ta). Examples of the Group 6 metal of the periodic table include chromium (Cr), molybdenum (Mo), and tungsten (W). Examples of the Group 7 metal of the periodic table include manganese (Mn), technetium (Tc), and rhenium (Re). Examples of the Group 8 metal of the periodic table include iron (Fe), ruthenium (Ru), and osmium (Os). Examples of the Group 9 metal of the periodic table include cobalt (Co), rhodium (Rh), and iridium (Ir). Examples of the Group 10 metal of the periodic table include nickel (Ni), palladium (Pd), and platinum (Pt). In the embodiment of the present disclosure, the emitter electrode preferably contains at least one kind of metal selected from titanium (Ti), tantalum (Ta), and tungsten (W). Also, the electrode may contain a conductive metal oxide in the embodiment of the present disclosure. Examples of the conductive metal oxide contained in the electrode include metal oxide conductive films of tin oxide, zinc oxide, indium oxide, indium tin oxide (ITO), indium zinc oxide (IZO), and the like. The electrode may be configured of a single layer or may include a plurality of metal layers. A method of forming the electrode is not particularly limited. Specific examples of a method of forming the electrode include a dry method, a wet method, and a mist CVD method. Examples of the dry method include sputtering, vacuum deposition, and CVD. Examples of the wet method include screen printing and die coating.

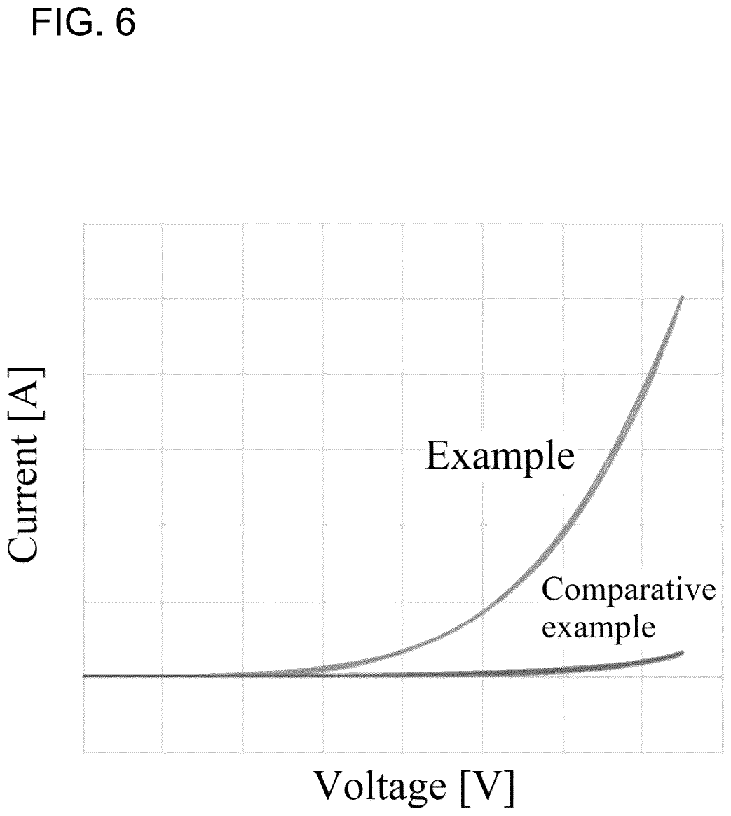

In an example, a semiconductor diode (PiN diode) including at least layers corresponding to the second p type oxide semiconductor layer 2b, the n− type oxide semiconductor layer 1a, and the n+ type oxide semiconductor layer 1b in the IGBT in FIG. 1, respectively, was experimentally produced in order to check a conductivity modulation effect achieved by hole injection from the second p type oxide semiconductor. Note that an α-Ir₂O₃ layer was used as the second p type oxide semiconductor layer, an α-Ga₂O₃ layer was used as the n− type oxide semiconductor layer, and a tin-doped α-Ga₂O₃ layer was used as the n+ type oxide semiconductor layer. Note that in the example, crystal growth was performed in the order of the n+ type oxide semiconductor layer, the n− type oxide semiconductor layer, and the second p type oxide semiconductor layer using the mist CVD device illustrated in FIG. 7. A result of I-V measurement of the semiconductor device produced in the example is shown in FIG. 6. FIG. 6 illustrates, as a comparative example, an example of a semiconductor device produced similarly to the example other than that a Schottky electrode was formed instead of the layer (α-Ir₂O₃ layer) corresponding to the second p type oxide semiconductor layer. As is obvious from FIG. 6, it is possible to recognize that the second p type oxide semiconductor layer in the embodiment of the present disclosure satisfactorily causes conductivity modulation in combination with the n− type oxide semiconductor layer with a large band gap, such as gallium oxide, in particular. Note that it was possible to know that satisfactory conductivity modulation was observed in a case where film formation was performed by setting the film formation temperature of the second p type oxide semiconductor layer within a range of 530° C. to 570° C. in the embodiment of the present disclosure. This is new knowledge obtained by stacking the α-Ir₂O₃ layer on the α-Ga₂O₃ layer under specific conditions. Note that a similar result was obtained even in a case where the α-Ir₂O₃ layer was replaced with an α-(Ir, Ga)₂O₃ layer.

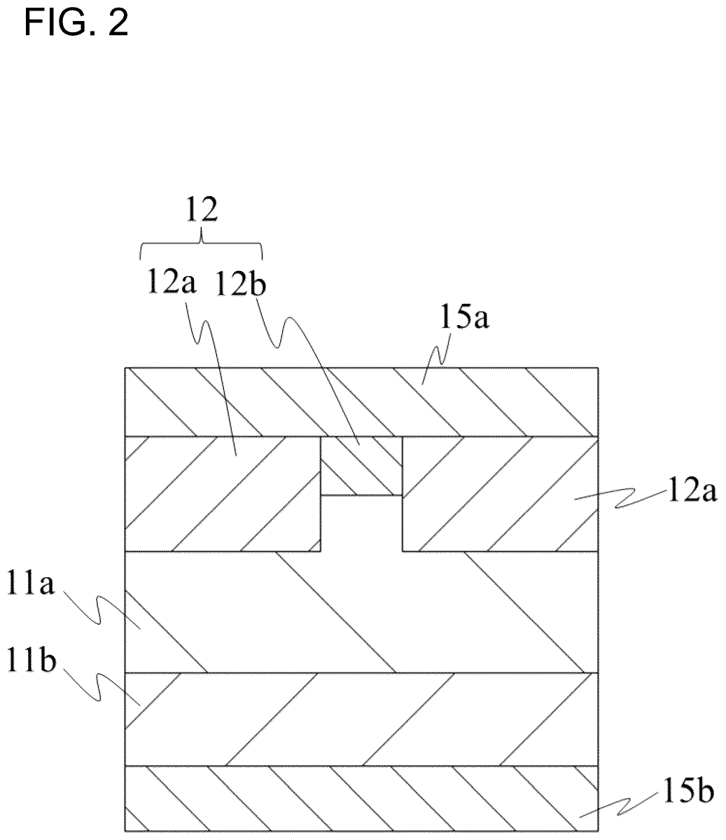

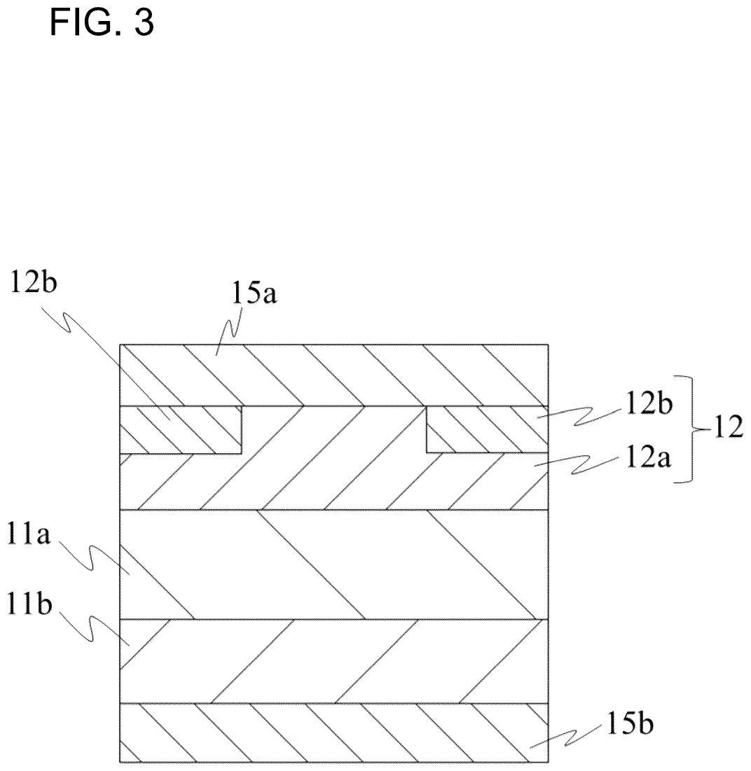

FIGS. 2 and 3 are diagrams schematically illustrating major parts of a PiN diode (PND) which is one of preferred embodiments of the present disclosure. The PND illustrated in FIGS. 2 and 3 include an ohmic electrode 15b (cathode electrode), an n+ type oxide semiconductor layer 11b, an n− type oxide semiconductor layer (i type oxide semiconductor layer) 11a, a p type oxide semiconductor layer 12 including a first oxide semiconductor layer 12a and a second oxide semiconductor layer 12b as a hole supply layer, and an ohmic electrode 15a (anode electrode). In the PND in FIGS. 2 and 3, the n+ type oxide semiconductor layer 11b and the n− type oxide semiconductor layer (i type oxide semiconductor layer) 11a are stacked in this order on the ohmic electrode 15b. Also, the first oxide semiconductor layer 12a and the second oxide semiconductor layer 12b are stacked on the n− type oxide semiconductor layer 11a. The ohmic electrode 15a is disposed on the first oxide semiconductor layer 12a and/or the second oxide semiconductor layer 12b. Once a voltage in a forward direction is applied to the PND, holes are injected from the first oxide semiconductor layer 12a and the second oxide semiconductor layer 12b and electrons are injected from the n+ type oxide semiconductor layer 11b into the n− type oxide semiconductor layer 11a, and a current flows from the ohmic electrode 15a to the ohmic electrode 15b. Note that in the semiconductor device in FIGS. 2 and 3, the p type oxide semiconductor layer 12 and the n− type oxide semiconductor layer 11a form a main junction.

Examples of a constituent material of the ohmic electrodes 15a and 15b include materials and the like exemplified as the constituent materials of the collector electrode, the emitter electrode, and the gate electrode. Also, a method of forming the ohmic electrodes is not particularly limited. Specific examples of the method of forming the ohmic electrodes include a dry method, a wet method, and a mist CVD method. Examples of the dry method include sputtering, vacuum deposition, and CVD. Examples of the wet method include screen printing and die coating.

In the PiN diode in FIGS. 2 and 3, a bottom surface of the first oxide semiconductor layer is located on the side closer to the n type oxide semiconductor layer (the n− type oxide semiconductor layer, the n+ type oxide semiconductor layer) in the stacking direction (the up-down direction in the drawings) of the semiconductor device than a bottom surface of the second oxide semiconductor layer. With such a structure, it is possible to exhibit excellent semiconductor characteristics while more satisfactorily preventing avalanche breakdown during an application of a reverse bias even in a case where the band gap of the second oxide semiconductor layer is smaller than the band gap of the first oxide semiconductor layer, for example. Also, hole carrier density of the second oxide semiconductor layer is preferably greater than hole carrier density of the first oxide semiconductor layer. It is possible to cause hole injection from the p type oxide semiconductor layer in the forward direction to more satisfactorily function by setting the hole carrier density within such a preferable range. Although the second oxide semiconductor layer is selectively formed in FIG. 3, the second oxide semiconductor layer may be formed on the entire surface.

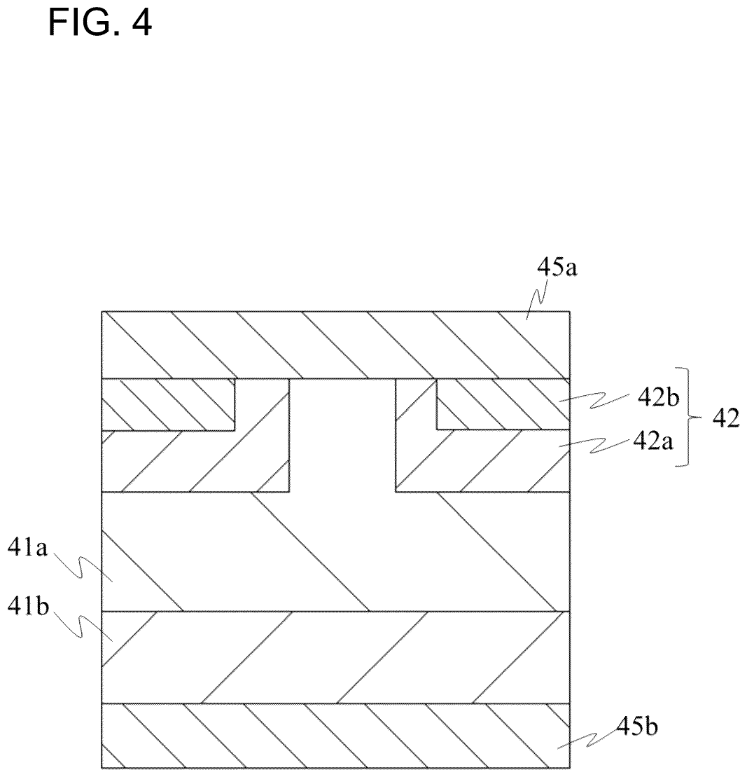

FIG. 4 is a diagram schematically illustrating major parts of a junction barrier Schottky diode (JBS) which is one of preferred embodiments of the present disclosure. The JBS illustrated in FIG. 4 includes an n+ type oxide semiconductor layer 41b, an n− type oxide semiconductor layer 41a, a p type oxide semiconductor layer (barrier layer) 42 including a first oxide semiconductor layer 42a and a second oxide semiconductor layer 42b as a hole supply layer, and a Schottky electrode 45a. In the JBS in FIG. 4, the n+ type oxide semiconductor layer 41b and the n− type oxide semiconductor layer 41a are stacked in this order on the ohmic electrode 45b. Also, the first oxide semiconductor layer 42a and the second oxide semiconductor layer 42b are disposed as the barrier layer 42 in at least a part between the n− type oxide semiconductor layer 41a and the Schottky electrode 45a. Note that in the semiconductor device in FIG. 4, the p type oxide semiconductor layer 42 and the n− type oxide semiconductor layer 41a form a main junction. Once a negative voltage is applied to the ohmic electrode 45b with reference to a potential of the Schottky electrode 45a in the ON state of the JBS in FIG. 4, the JBS is brought into a state where a current flows from the Schottky electrode 45a to the ohmic electrode 45b, that is, a conductive state (ON state). Moreover, once a positive voltage is applied to the ohmic electrode 45b with reference to the potential of the Schottky electrode 45a, a depletion layer is formed at an interface of the junction (Schottky junction) between the Schottky electrode 45a and the n− type oxide semiconductor layer 41a, and a depletion layer is formed at an interference of the junction (PN junction) between the first oxide semiconductor layer 42a and the n− type oxide semiconductor layer 41a. In this manner, electric field intensity at the Schottky junction interface is suppressed, a leakage current is reduced, and voltage withstanding property is improved by the depletion layer spreading from the adjacent barrier layer (first p type oxide semiconductor layer) 42a.

In the JBS in FIG. 4, a bottom surface of the first oxide semiconductor layer 42a is located on the side closer to the n type oxide semiconductor layer (the n− type oxide semiconductor layer, the n+ type oxide semiconductor layer) in the stacking direction (the up-down direction in the drawing) of the semiconductor device than a bottom surface of the second oxide semiconductor layer 42b. With such a structure, it is possible to exhibit excellent semiconductor characteristics while more satisfactorily preventing avalanche breakdown during an application of a reverse bias even in a case where the band gap of the second oxide semiconductor layer is smaller than the band gap of the first oxide semiconductor layer, for example. Moreover, hole carrier density of the second p type oxide semiconductor layer 42b is preferably greater than hole carrier density of the first p type oxide semiconductor layer 42a. It is possible to cause hole injection from the second oxide semiconductor layer in the forward direction to more satisfactorily function by setting the hole carrier density within such a preferable range.

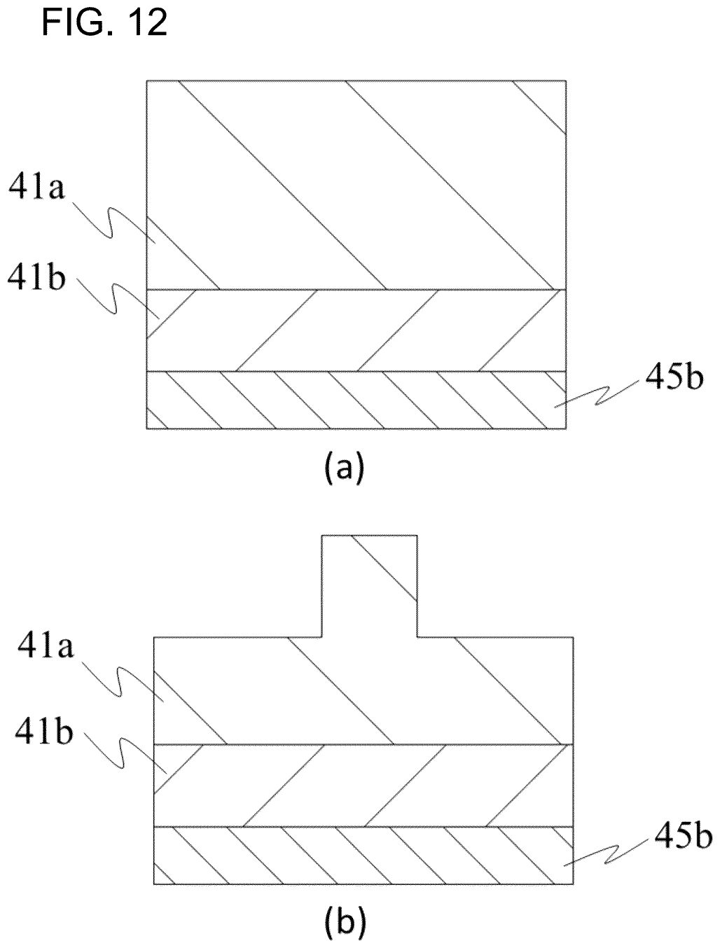

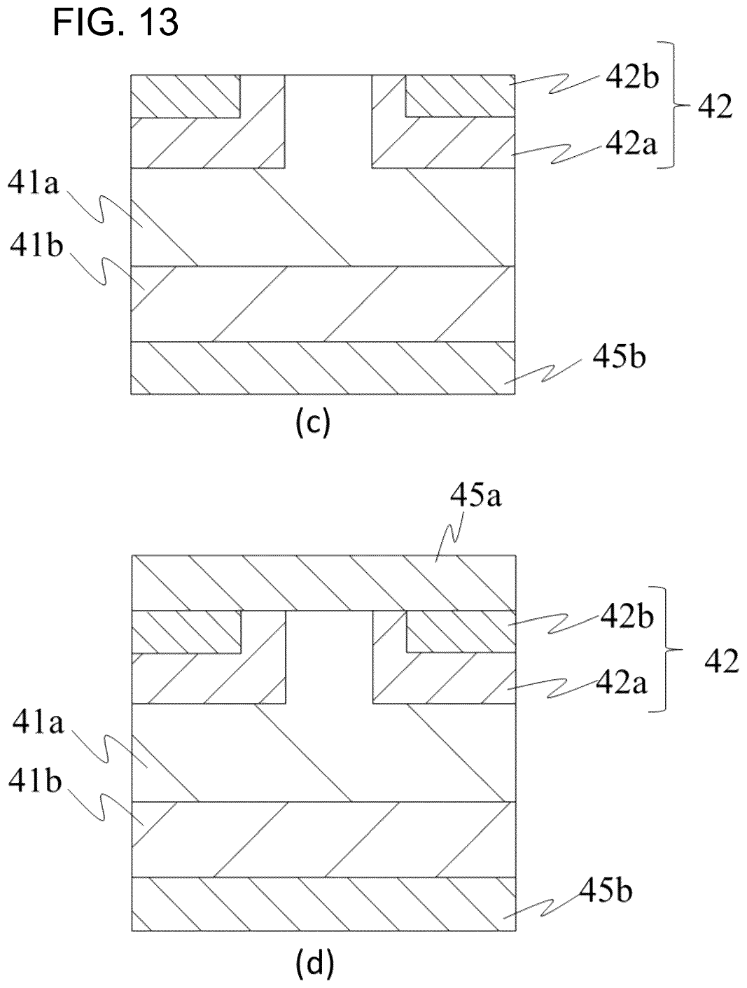

Hereinafter, the present disclosure will be more specifically described using a preferred example of manufacturing the semiconductor device in FIG. 4. FIG. 12(a) illustrates a multilayered body in which the ohmic electrode 45b is stacked on the n+ type oxide semiconductor layer 41b and the n− type oxide semiconductor layer 41a is formed on the n+ type oxide semiconductor layer 41b on the side opposite to the ohmic electrode 45b. An opening is formed in the multilayered body in FIG. 12(a) as in FIG. 12(b) using a known etching technology. After the multilayered body in FIG. 12(b) is obtained, the first oxide semiconductor layer 42a and the second oxide semiconductor layer 42b are formed using photolithography and a known etching technology to thereby obtain a multilayered body in FIG. 13(c). Note that the formation of the first oxide semiconductor layer 42a and the second oxide semiconductor layer 42b is preferably formed through crystal growth using the aforementioned method of forming the semiconductor layers. After the multilayered body in FIG. 13(c) is obtained, the Schottky electrode 45a is formed using the aforementioned dry method or wet method to thereby obtain the semiconductor device in FIG. 13(d).

FIG. 5 is a diagram schematically illustrating major parts of a metal-oxide-semiconductor field-effect transistor (MOSFET) which is one of preferred embodiments of the present disclosure. The MOSFET in FIG. 5 includes a drain electrode 35c, an n type oxide semiconductor layer 31, an n− type oxide semiconductor layer (drift layer) 31a, a p type oxide semiconductor layer (p well layer) 32 including a first oxide semiconductor layer 32a and a second oxide semiconductor layer 32b as a hole supply layer, an n+ type oxide semiconductor layer (n type source layer) 31b, a gate insulating film 34, a source electrode 35b, and a gate electrode 35a. In the MOSFET in FIG. 5, the n type oxide semiconductor layer 31 and the n− type oxide semiconductor layer 31a are stacked in this order on the drain electrode 35c. Also, the first oxide semiconductor layer 32a and the second oxide semiconductor layer 32b as the p well layer are disposed on the n− type oxide semiconductor layer 31a. The MOSFET in FIG. 5 further includes the n+ type oxide semiconductor layer 31b inside the first oxide semiconductor layer 32a. The gate electrode 35a is disposed above the first oxide semiconductor layer 32a via the gate insulating film 34. Note that the source electrode 35b is disposed to be in contact with the n+ type oxide semiconductor layer 31b and the second oxide semiconductor layer 32b. Also, the first oxide semiconductor layer 32a and the n− type oxide semiconductor layer 31a form a main junction in the MOSFET in FIG. 5. The MOSFET in FIG. 5 is a diode incorporated MOSFET, and a parasitic PN junction including the first p type oxide semiconductor layer 32a and the n− type oxide semiconductor layer 31a and an incorporated Schottky barrier diode (SBD) including the source electrode 35b and the n− type oxide semiconductor layer 31a are present. When the MOSFET in FIG. 5 is turned on, a gate voltage that is equal to or greater than a threshold voltage is applied, a channel is formed in the first p type oxide semiconductor layer 32a within a range in which the first p type oxide semiconductor layer 32a is in contact with the gate electrode 35a via the gate insulating film 34, and a current flows from the drain electrode 35c to the source electrode 35b. Also, when the MOSFET is turned off, the application voltage between the drain-source electrodes is inhibited by the PN junction configured between the first p type oxide semiconductor layer 32a and the n− type oxide semiconductor layer 31a. In a case where a positive voltage with respect to the drain electrode 35c is applied to the source electrode 35b, a current flows through the incorporated SBD. In a case where an excessive current flows, it is possible to cause the large current to flow with a low ON voltage in a bipolar mode by holes being injected from the p type oxide semiconductor layer (p well layer) 32. Moreover, in a case where a negative voltage with respect to the drain electrode 35c is applied to the source electrode 35b, the application voltage between the drain-source electrode is inhibited by the parasitic PN junction and the incorporated SBD. Note that although the case where the MOSFET in FIG. 5 is of a planar gate type has been described as an example, the MOSFET may be of a trench gate type in the embodiment of the present disclosure.

In the MOSFET in FIG. 5, a bottom surface of the first p type oxide semiconductor layer 32a is located on the side closer to the n type oxide semiconductor layer (the n− type oxide semiconductor layer, the n+ type oxide semiconductor layer) in the stacking direction (the up-down direction in the drawing) of the semiconductor device than a bottom surface of the second p type oxide semiconductor layer 32b. With such a structure, it is possible to exhibit excellent semiconductor characteristics while more satisfactorily preventing avalanche breakdown during an application of a reverse bias even in a case where the band gap of the second oxide semiconductor layer is smaller than the band gap of the first oxide semiconductor layer, for example. Also, hole carrier density of the second p type oxide semiconductor layer 32b is greater than hole carrier density of the first p type oxide semiconductor layer 32a. In a case where an excessive current flows through the incorporated Schottky barrier diode, it is possible to cause a large current to flow with a low ON voltage in a bipolar mode through hole injection from the second p type oxide semiconductor layer 32b by setting the hole carrier density within such a preferable range. Moreover, it is possible to reduce ohmic contact resistance with the source electrode 35b and to prevent breakage of the element by causing an avalanche current at the time of turning-off to escape to the outside of the element.

Note that it is also possible to combine a plurality of embodiments of the present disclosure described above or to apply some of the components to another embodiment, and such configurations also belong to embodiments of the present disclosure.

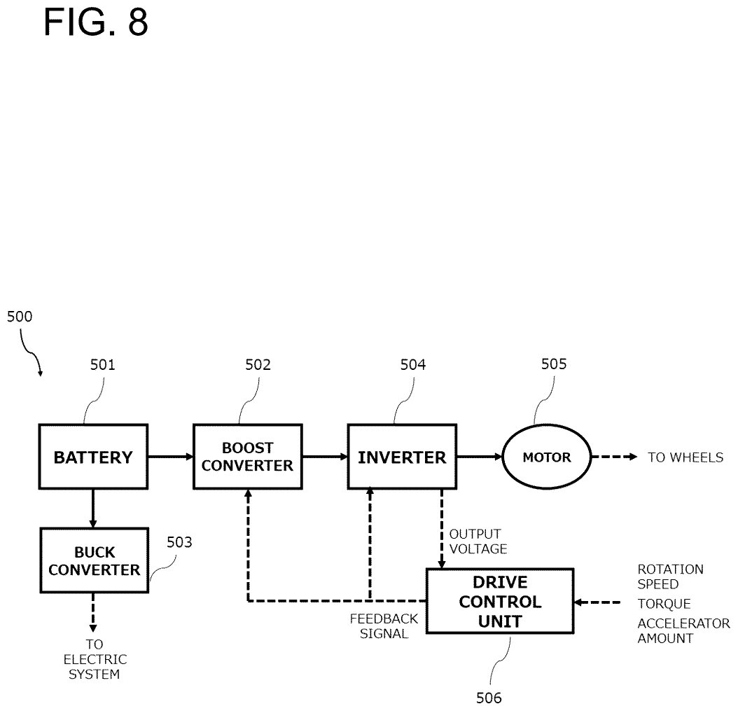

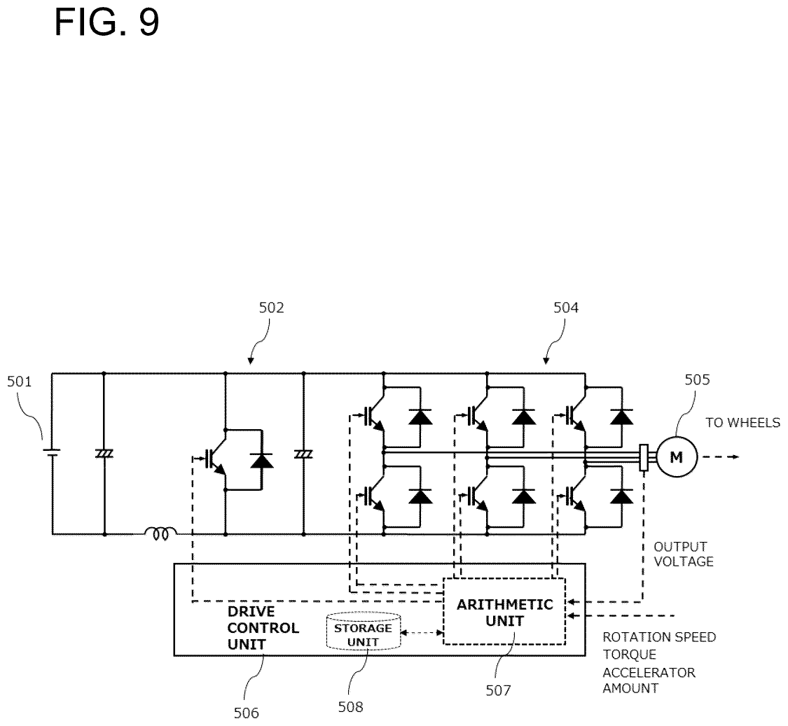

In order to exhibit the functions described above, the semiconductor device of the disclosure described above can be applied to a power converter such as an inverter or a converter. More specifically, it can be applied as a thyristor, a power transistor, an IGBT (Insulated Gate Bipolar Transistor), a MOSFET (Metal-Oxide-Semiconductor Field Effect Transistor), a PND that is rectifying elements (PiN Diode), JBS (Junction Barrier Schottky Diode) or the like as a switching element. FIG. 8 is a block diagram illustrating an exemplary control system applying a semiconductor device according to an embodiment of the disclosure, and FIG. 9 is a circuit diagram of the control system particularly suitable for applying to a control system of an electric vehicle.

As shown in FIG. 8, the control system 500 includes a battery (power supply) 501, a boost converter 502, a buck converter 503, an inverter 504, a motor (driving object) 505, a drive control unit 506, which are mounted on an electric vehicle. The battery 501 consists of, for example, a storage battery such as a nickel hydrogen battery or a lithium-ion battery. The battery 501 can store electric power by charging at the power supply station or regenerating at the time of deceleration, and to output a direct current (DC) voltage required for the operation of the driving system and the electrical system of the electric vehicle. The boost converter 502 is, for example, a voltage converter in which a chopper circuit is mounted, and can step-up DC voltage of, for example, 200V supplied from the battery 501 to, for example, 650V by switching operations of the chopper circuit. The step-up voltage can be supplied to a traveling system such as a motor. The buck converter 503 is also a voltage converter in which a chopper circuit is mounted, and can step-down DC voltage of, for example, 200V supplied from the battery 501 to, for example, about 12V. The step-down voltage can be supplied to an electric system including a power window, a power steering, or an electric device mounted on a vehicle.

The inverter 504 converts the DC voltage supplied from the boost converter 502 into three-phase alternating current (AC) voltage by switching operations, and outputs to the motor 505. The motor 505 is a three-phase AC motor constituting the traveling system of an electric vehicle, and is driven by an AC voltage of the three-phase output from the inverter 504. The rotational driving force is transmitted to the wheels of the electric vehicle via a transmission mechanism (not shown).

On the other hand, actual values such as rotation speed and torque of the wheels, the amount of depression of the accelerator pedal (accelerator amount) are measured from an electric vehicle in cruising by using various sensors (not shown), The signals thus measured are input to the drive control unit 506. The output voltage value of the inverter 504 is also input to the drive control unit 506 at the same time. The drive control unit 506 has a function of a controller including an arithmetic unit such as a CPU (Central Processing Unit) and a data storage unit such as a memory, and generates a control signal using the inputted measurement signal and outputs the control signal as a feedback signal to the inverters 504, thereby controlling the switching operation by the switching elements. The AC voltage supplied to the motor 505 from the inverter 504 is thus corrected instantaneously, and the driving control of the electric vehicle can be executed accurately. Safety and comfortable operation of the electric vehicle is thereby realized. In addition, it is also possible to control the output voltage to the inverter 504 by providing a feedback signal from the drive control unit 506 to the boost converter 502.

FIG. 9 is a circuit configuration excluding the buck converter 503 in FIG. 8, in other words, a circuit configuration showing a configuration only for driving the motor 505. As shown in the Fig. B, the semiconductor device of the disclosure is provided for switching control by, for example, being applied to the boost controller 502 and the inverter 504 as a Schottky barrier diode. The boost converter 502 performs chopper control by incorporating the semiconductor device into the chopper circuit of the boost converter 502. Similarly, the inverter 504 performs switching control by incorporating the semiconductor device into the switching circuit including an IGBT of the inverter 504. The current can be stabilized by interposing an inductor (such as a coil) at the output of the battery 501. Also, the voltage can be stabilized by interposing a capacitor (such as an electrolytic capacitor) between each of the battery 501, the boost converter 502, and the inverter 504.

As indicated by a dotted line in FIG. 9, an arithmetic unit 507 including a CPU (Central Processing Unit) and a storage unit 508 including a nonvolatile memory are provided in the drive control unit 506. Signal input to the drive control unit 506 is given to the arithmetic unit 507, and a feedback signal for each semiconductor element is generated by performing the programmed operation as necessary. The storage unit 508 temporarily holds the calculation result by the calculation unit 507, stores physical constants and functions necessary for driving control in the form of a table, and outputs the physical constants, functions, and the like to the arithmetic unit 507 as appropriate. The arithmetic unit 507 and the storage unit 508 can be provided by a known configuration, and the processing capability and the like thereof can be arbitrarily selected.

As shown in FIGS. 8 and 9, a diode and a switching element such as a thyristor, a power transistor, an IGBT, a MOSFET and the like is employed for the switching operation of the boost converter 502, the buck converter 503 and the inverter 504 in the control system 500. The use of gallium oxide (Ga₂O₃) specifically corundum-type gallium oxide (α-Ga₂O₃) as its materials for these semiconductor devices greatly improves switching properties. Further, extremely outstanding switching performance can be expected and miniaturization and cost reduction of the control system 500 can be realized by applying a semiconductor film or a semiconductor device of the disclosure. That is, each of the boost converter 502, the buck converter 503 and the inverter 504 can be expected to have the benefit of the disclosure, and the effect and the advantages can be expected in any one or combination of the boost converter 502, the buck converter 503 and the inverter 504, or in any one of the boost converter 502, the buck converter 503 and the inverter 504 together with the drive control unit 506.

The control system 500 described above is not only applicable to the control system of an electric vehicle of the semiconductor device of the disclosure, but can be applied to a control system for any applications such as to step-up and step-down the power from a DC power source, or convert the power from a DC to an AC. It is also possible to use a power source such as a solar cell as a battery.

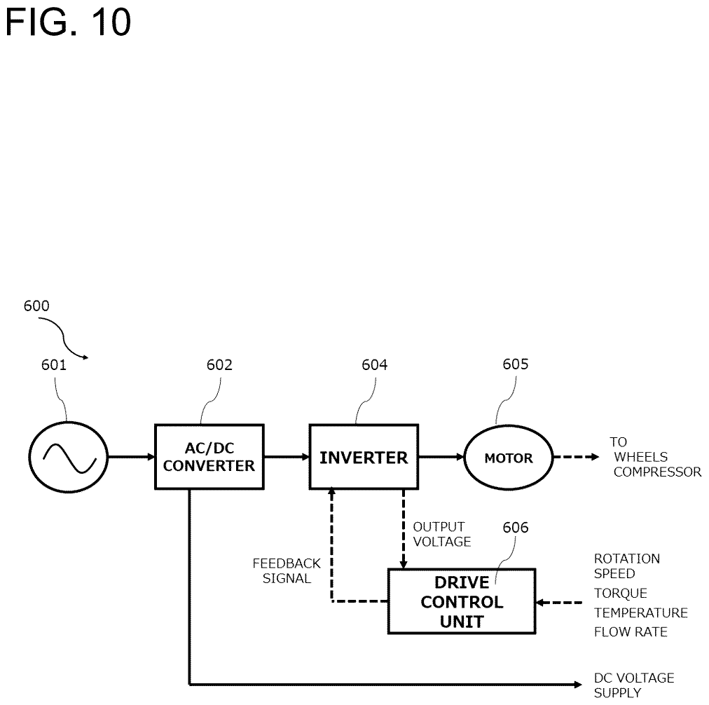

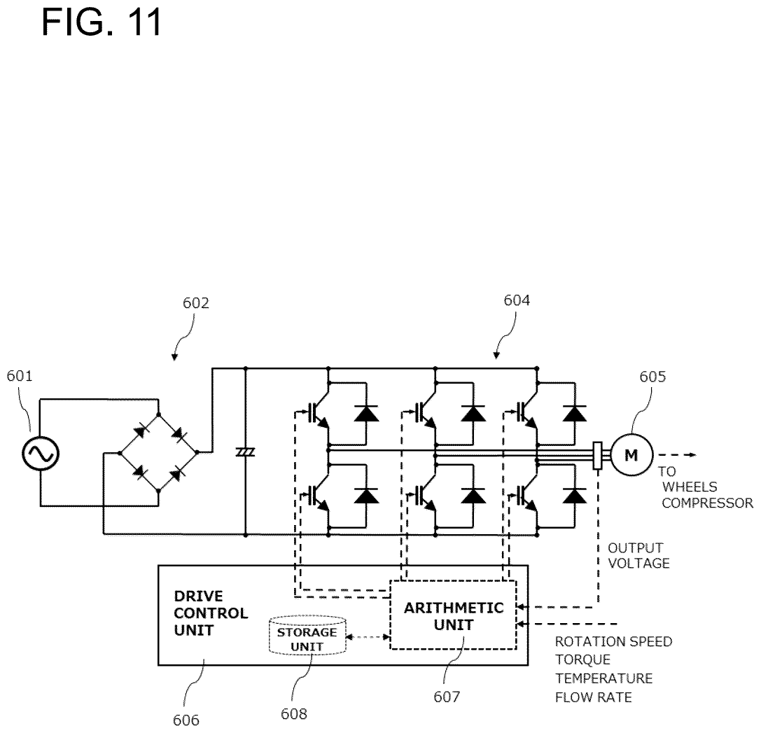

FIG. 10 is a block diagram illustrating another exemplary control system applying a semiconductor device according to an embodiment of the disclosure, and FIG. 11 is a circuit diagram of the control system suitable for applying to infrastructure equipment and home appliances or the like operable by the power from the AC power source.

As shown in FIG. 10, the control system 600 is provided for inputting power supplied from an external, such as a three-phase AC power source (power supply) 601, and includes an AC/DC converter 602, an inverter 604, a motor (driving object) 605 and a drive control unit 606 that can be applied to various devices described later. The three-phase AC power supply 601 is, for example, a power plant (such as a thermal, hydraulic, geothermal, or nuclear plant) of an electric power company, whose output is supplied as an AC voltage while being downgraded through substations. Further, the three-phase AC power supply 601 is installed in a building or a neighboring facility in the form of a private power generator or the like for supplying the generated power via a power cable. The AC/DC converter 602 is a voltage converter for converting AC voltage to DC voltage. The AC/DC converter 602 converts AC voltage of 100V or 200V supplied from the three-phase AC power supply 601 to a predetermined DC voltage. Specifically, AC voltage is converted by a transformer to a desired, commonly used voltage such as 3. 3V, 5V, or 12V. When the driving object is a motor, conversion to 12V is performed. It is possible to adopt a single-phase AC power supply in place of the three-phase AC power supply. In this case, same system configuration can be realized if an AC/DC converter of the single-phase input is employed.

The inverter 604 converts the DC voltage supplied from the AC/DC converter 602 into three-phase AC voltage by switching operations and outputs to the motor 605. Configuration of the motor 605 is variable depending on the control object. It can be a wheel if the control object is a train, can be a pump and various power source if the control objects a factory equipment, can be a three-phase AC motor for driving a compressor or the like if the control object is a home appliance. The motor 605 is driven to rotate by the three-phase AC voltage output from the inverter 604, and transmits the rotational driving force to the driving object (not shown).

There are many kinds of driving objects such as personal computer, LED lighting equipment, video equipment, audio equipment and the like capable of directly supplying a DC voltage output from the AC/DC inverter 602. In that case the inverter 604 becomes unnecessary in the control system 600, and a DC voltage from the AC/DC inverter 602 is supplied to the driving object directly as shown in FIG. 11. Here, DC voltage of 3.3V is supplied to personal computers and DC voltage of 5V is supplied to the LED lighting device for example.

On the other hand, rotation speed and torque of the driving object, measured values such as the temperature and flow rate of the peripheral environment of the driving object, for example, is measured using various sensors (not shown), these measured signals are input to the drive control unit 606. At the same time, the output voltage value of the inverter 604 is also input to the drive control unit 606. Based on these measured signals, the drive control unit 606 provides a feedback signal to the inverter 604 thereby controls switching operations by the switching element of the inverter 604. The AC voltage supplied to the motor 605 from the inverter 604 is thus corrected instantaneously, and the operation control of the driving object can be executed accurately. Stable operation of the driving object is thereby realized. In addition, when the driving object can be driven by a DC voltage, as described above, feedback control of the AC/DC controller 602 is possible in place of feedback control of the inverter 604.

FIG. 11 shows the circuit configuration of FIG. 10. As shown in FIG. 11, the semiconductor device of the disclosure is provided for switching control by, for example, being applied to the AC/DC converter 602 and the inverter 604 as a Schottky barrier diode. The AC/DC converter 602 has, for example, a circuit configuration in which Schottky barrier diodes are arranged in a bridge-shaped, to perform a direct-current conversion by converting and rectifying the negative component of the input voltage to a positive voltage. Schottky barrier diodes can also be applied to a switching circuit in IGBT of the inverter 604 to perform switching control. The voltage can be stabilized by interposing a capacitor (such as an electrolytic capacitor) between the AC/DC converter 602 and the inverter 604.

As indicated by a dotted line in FIG. 11, an arithmetic unit 607 including a CPU and a storage unit 608 including a nonvolatile memory are provided in the drive control unit 606. Signal input to the drive control unit 606 is given to the arithmetic unit 607, and a feedback signal for each semiconductor element is generated by performing the programmed operation as necessary. The storage unit 608 temporarily holds the calculation result by the arithmetic unit 607, stores physical constants and functions necessary for driving control in the form of a table, and outputs the physical constants, functions, and the like to the arithmetic unit 607 as appropriate. The arithmetic unit 607 and the storage unit 608 can be provided by a known configuration, and the processing capability and the like thereof can be arbitrarily selected.

In such a control system 600, similarly to the control system 500 shown in FIGS. 8 and 9, a diode or a switching element such as a thyristor, a power transistor, an IGBT, a MOSFET or the like is also applied for the purpose of the rectification operation and switching operation of the AC/DC converter 602 and the inverter 604. Switching performance can be improved by the use of gallium oxide (Ga 2 O3), particularly corundum-type gallium oxide (α-Ga₂O₃), as materials for these semiconductor elements. Further, extremely outstanding switching performance can be expected and miniaturization and cost reduction of the control system 600 can be realized by applying a semiconductor film or a semiconductor device of the disclosure. That is, each of the AC/DC converter 602 and the inverter 604 can be expected to have the benefit of the disclosure, and the effects and the advantages of the disclosure can be expected in any one or combination of the AC/DC converter 602 and the inverter 604, or in any of the AC/DC converter 602 and the inverter 604 together with the drive control unit 606.

Although the motor 605 has been exemplified in FIGS. 10 and 11, the driving object is not necessarily limited to those that operate mechanically. Many devices that require an AC voltage can be a driving object. It is possible to apply the control system 600 as long as electric power is obtained from AC power source to drive the driving object. The control system 600 can be applied to the driving control of any electric equipment such as infrastructure equipment (electric power facilities such as buildings and factories, telecommunication facilities, traffic control facilities, water and sewage treatment facilities, system equipment, labor-saving equipment, trains and the like) and home appliances (refrigerators, washing machines, personal computers, LED lighting equipment, video equipment, audio equipment and the like).

### INDUSTRIAL APPLICABILITY

Although the semiconductor device according to the present disclosure is able to be used in any fields such as fields of semiconductors (compound semiconductor electronic devices, for example), electronic parts/electric device parts, optical/electronic photograph-related devices, industrial members, and the like, the semiconductor device is effective for power devices, in particular.

The embodiments of the present invention are exemplified in all respects, and the scope of the present invention includes all modifications within the meaning and scope equivalent to the scope of claims.

### REFERENCE SIGNS LIST

1 n type oxide semiconductor layer (buffer layer)
1a n− type oxide semiconductor layer (drift layer)
1b n+ type oxide semiconductor layer (emitter layer)
2a First p type oxide semiconductor layer (well layer, first oxide semiconductor layer)
2b Second p type oxide semiconductor layer (hole supply layer, collector layer, second oxide semiconductor layer)
2c Third p type oxide semiconductor layer (p contact layer)
4 Gate insulating film
5a Gate electrode
5b Emitter electrode
5c Collector electrode
11a n− type oxide semiconductor layer (drift layer)
11b n+ type oxide semiconductor layer (cathode layer)
12 p type oxide semiconductor layer (anode layer)
12a First oxide semiconductor layer (first p type oxide semiconductor layer)
12b Second oxide semiconductor layer (second p type oxide semiconductor layer)
15a Ohmic electrode (anode electrode)
15b Ohmic electrode (cathode electrode)
21 Film formation device (mist CVD device)
22a Carrier gas source
22b Carrier gas (diluted) source
23a Flow regulating valve
23b Flow regulating valve
24 Mist generation source
24a Raw material solution
24b Raw material fine particle
25 Container
25a Water
26 Ultrasonic vibrator
27 Film formation chamber
28 Hot plate
29 Supply pipe
30 Substrate
31 n type oxide semiconductor layer (drain layer)
31a n− type oxide semiconductor layer (drift layer)
31b n+ type oxide semiconductor layer (source layer)
32 p type oxide semiconductor layer (p well layer)
32a First p type oxide semiconductor layer (first oxide semiconductor layer)
32b Second p type oxide semiconductor layer (second oxide semiconductor layer)
34 Gate insulating film
35a Gate electrode
35b Source electrode
35c Drain electrode
41a n− type oxide semiconductor layer (drift layer)
41b n+ type oxide semiconductor layer (cathode layer)
42 p type oxide semiconductor layer (barrier layer)
42a First oxide semiconductor layer (first p type oxide semiconductor layer)
42b Second oxide semiconductor layer (second p type oxide semiconductor layer)
45a Schottky electrode (anode electrode)
45b Ohmic electrode (cathode electrode)
500 Control system
501 Battery (power source)
502 Boost converter
503 Step-down converter
504 Inverter
505 Motor (drive target)
506 Drive control unit
507 Calculation unit
508 Storage unit
600 Control system
601 Three-phase alternating power source (power source)
602 AC/DC converter
604 Inverter
605 Motor (drive target)
606 Drive control unit
607 Calculation unit
608 Storage unit

What is claimed is:

1. A semiconductor device comprising at least:
an n type oxide semiconductor layer;
a first p type oxide semiconductor layer that forms a main junction with the n type oxide semiconductor layer, and
a hole supply layer,
wherein the hole supply layer includes a second p type oxide semiconductor layer that is different from the first p type oxide semiconductor layer.

2. The semiconductor device according to claim 1,
wherein the first p type oxide semiconductor layer and the second p type oxide semiconductor layer has a different composition from each other.

3. The semiconductor device according to claim 1,
wherein a band gap of the first p type oxide semiconductor layer is greater than a band gap of the second p type oxide semiconductor layer.

4. The semiconductor device according to claim 1,
wherein the first p type oxide semiconductor layer and the second p type oxide semiconductor layer are crystal growth layers.

5. The semiconductor device according to claim 1,
wherein a bottom surface of the first p type oxide semiconductor layer is located on a side closer to the n type oxide semiconductor layer in a stacking direction of the semiconductor device than a bottom surface of the second p type oxide semiconductor layer.

6. The semiconductor device according to claim 1,
wherein the n type oxide semiconductor layer contains, as major components, oxides of one or more metals selected from aluminum, gallium, and indium.

7. The semiconductor device according to claim 1,
wherein the n type oxide semiconductor layer has a corundum structure.

8. The semiconductor device according to claim 1,
wherein the first p type oxide semiconductor layer contains, as major components, oxides of one or more metals selected from aluminum, gallium, and indium.

9. The semiconductor device according to claim 1,
wherein the second p type oxide semiconductor layer contains at least oxide of Group 9 metal of the periodic table.

10. The semiconductor device according to claim 9,
wherein the Group 9 metal of the periodic table includes iridium.

11. The semiconductor device according to claim 9,
wherein the second p type oxide semiconductor layer further contains oxides of one or more metals selected from aluminum, gallium, and indium.

12. The semiconductor device according to claim 1,
wherein the first p type oxide semiconductor layer has a corundum structure.

13. The semiconductor device according to claim 1,
wherein the second p type oxide semiconductor layer has a corundum structure.

14. A semiconductor device comprising at least:
a collector layer;
a drift layer; and
a well layer,
the drift layer including an n type oxide semiconductor layer, the well layer including a first oxide semiconductor layer, the collector layer including a second oxide semiconductor layer that is different from the first oxide semiconductor layer and being an insulated gate bipolar transistor.

15. A semiconductor device comprising at least:
an n type oxide semiconductor layer;
a Schottky electrode that is provided on the n type oxide semiconductor layer; and
a barrier layer that is provided in at least a part between the n type oxide semiconductor layer and the Schottky electrode,
the barrier layer including a first oxide semiconductor layer and a second oxide semiconductor layer that is different from the first oxide semiconductor layer and being a junction barrier Schottky diode.

16. A semiconductor device comprising at least:
a p type oxide semiconductor layer,
an i type oxide semiconductor layer, and
an n type oxide semiconductor layer,
the p type oxide semiconductor layer including a first oxide semiconductor layer and a second oxide semiconductor layer that is different from the first oxide semiconductor layer and being a PiN diode.

17. The semiconductor device according to claim 14,
wherein the first oxide semiconductor layer and the second oxide semiconductor layer has a different composition from each other.

18. The semiconductor device according to claim 14,
wherein a band gap of the first oxide semiconductor layer is greater than a band gap of the second oxide semiconductor layer.

19. The semiconductor device according to claim 14,
wherein a bottom surface of the first oxide semiconductor layer is located on a side closer to the n type oxide semiconductor layer in a stacking direction of the semiconductor device than a bottom surface of the second oxide semiconductor layer.

20. The semiconductor device according to claim 14,
wherein hole carrier density of the second oxide semiconductor layer is greater than hole carrier density of the first oxide semiconductor layer.

21. A power conversion device that uses the semiconductor device according to claim 1.

22. A control system that uses the semiconductor device according to claim 1.
